(19) United States
(12) Patent Application Publication
(10) Pub. No.: US 2026/0229446 A1
(43) Pub. Date: Aug. 6, 2026

(54) Charged Particle Beam Device and Method for Producing and Observing Sample Piece

(71) Applicant: Hitachi High-Tech Corporation, Minato-ku, Tokyo (JP)

(72) Inventors: Yoshinori HIGASHI, Tokyo (JP); Mamoru OKABE, Tokyo (KR)

(21) Appl. No.: 19/147,747

(22) PCT Filed: Jan. 23, 2023
(86) PCT No.: PCT/JP2023/001972

§ 371 Date: Jul. 14, 2025

(51) Int. Cl. H01J 37/20; H01J 37/28

(52) U.S. Cl. CPC H01J 37/20; H01J 37/28; H01J 2237/20207; H01J 2237/20214; H01J 2237/20228; H01J 2237/20235; H01J 2237/31749

(57) ABSTRACT

Provided is a charged particle beam device which is capable of controlling a posture of a holder 6 capable of holding a plurality of carriers and which is capable of transporting the holder independently of a wafer stage 21. The charged particle beam device includes the wafer stage 21 configured to move with a wafer placed thereon, a needle configured to hold a sample piece separated and extracted from the wafer and transport the sample piece onto the plurality of carriers mounted on the holder, and a sub stage 22 configured to hold the holder and move independently of the wafer stage 21.

### TECHNICAL FIELD

The present disclosure relates to a charged particle beam device for processing and observing a sample and a method for producing and observing a sample piece.

### BACKGROUND ART

As miniaturization of a structure of a semiconductor device, an increase in a density of a circuit pattern, an increase in the number of layers of wiring, and the like progress, the importance of cross-sectional analysis of a wafer by using, for example, a transmission electron microscope (TEM) or a scanning transmission electron microscope (STEM) is increasing in order to improve reliability.

In imaging, observation, measurement, analysis, evaluation, test, and the like of a sample in a semiconductor manufacturing process, thinning of a designated portion of the wafer is performed by, for example, a focused ion beam (FIB) device. By the thinning, a sample piece (also referred to as lamella, thin film sample, or the like) in which a cross-sectional structure of the device is exposed is produced. The sample piece is transferred onto a carrier, and a cross-sectional structure of the sample piece is observed by, for example, a TEM device.

A microsampling method is known as a method for transferring a sample piece onto a carrier. In the microsampling method, a sample piece extracted from a sample by a microprobe is transferred onto a carrier (TEM mesh) in a charged particle beam device. In order to change a posture of the carrier after the sample piece is transferred onto the carrier, it is necessary to unload the carrier.

PTL 1 describes a charged particle beam device capable of performing processing by FIB and observation by a scanning electron microscope (SEM). The charged particle beam device includes a sample holder that holds and fixes a thin piece sample, and a sample stage on which the sample holder is placed. The sample stage may move in tri-axial directions of XYZ, tilt about a tilt axis orthogonal to an irradiation axis of the FIB, and rotate. The sample holder includes a rotary table that rotates about a holder shaft on a base placed on the sample stage, and a worm wheel that is accommodated in a recess formed in the rotary table and rotates about a roller shaft independently of the rotary table. A carrier to which the thin piece sample may be directly attached is provided at the uppermost portion of the worm wheel. With this structure, the charged particle beam device according to PTL 1 may change the posture of the carrier without unloading the carrier.

### CITATION LIST

### Patent Literature

PTL 1: JP2016-72089A

### SUMMARY OF INVENTION

### Technical Problem

However, the sample holder according to PTL 1 has the problem that it can hold only one carrier, limiting the number of sample pieces that can be transferred onto the carrier and lowering the efficiency of observation. In the charged particle beam device according to PTL 1, the sample stage on which the wafer is placed and the sample holder are transported as an integrated structure. Therefore, there are problems that it is difficult to transport the sample stage when the sample stage is increased in size, and the size of the wafer that may be placed on the sample stage is limited when the sample stage is reduced in size.

### Solution to Problem

An outline of a representative embodiment among embodiments disclosed in the present application will be briefly described as follows.

A charged particle beam device according to an embodiment that creates a sample piece from a wafer by using a charged particle beam, the device including: a charged particle beam column configured to emit the charged particle beam; a wafer stage configured to move with the wafer placed thereon; a sample piece transfer mechanism configured to hold the sample piece separated and extracted from the wafer and to transport the sample piece to a plurality of carriers mounted on a sample piece holder; and a sample piece holder stage configured to allow the sample piece holder to be detachably mounted thereon and to move independently of the wafer stage.

A method for producing and observing a sample piece according to an embodiment, the method including: irradiating a wafer with an ion beam to process the sample piece having a plane or a cross section of the wafer as an observation surface; attaching a sample piece transfer mechanism to the processed sample piece to extract and separate the sample piece from the wafer; attaching the sample piece to a carrier on a sample piece holder mounted on a sample piece holder stage that is tiltable and rotatable, such that the observation surface is parallel to a surface of the carrier; rotating the sample piece holder stage such that the observation surface of the sample piece is observable with an electron beam; and rotating the sample piece holder stage such that a back surface of the observation surface of the sample piece is observable with the electron beam.

A method for producing and observing a sample piece according to an embodiment, the method including: irradiating a wafer with an ion beam to process the sample piece having a plane or a cross section of the wafer as an observation surface; attaching a sample piece transfer mechanism to the processed sample piece to extract and separate the sample piece from the wafer; attaching the sample piece to a carrier on a sample piece holder mounted on a sample piece holder stage that is tiltable and rotatable, such that the observation surface is parallel to a surface of the carrier; tilting the sample piece holder stage such that the observation surface is parallel to an optical axis of the ion beam; rotating the sample piece holder stage such that the observation surface or a back surface of the observation surface is observable with the electron beam; processing the observation surface or a back surface of the sample piece by irradiation with the ion beam to thin the sample piece; changing a tilt of the sample piece holder stage to adjust an incident angle of the ion beam on the observation surface or the back surface such that the observation surface and the back surface are processed to be in parallel; and irradiating, with the electron beam, the observation surface or the back surface processed by the ion beam to observe a processing state of the observation surface or the back surface.

A method for producing and observing a sample piece according to an embodiment, the method including: irradiating a wafer with an ion beam to process the sample piece having a plane or a cross section of the wafer as an observation surface; attaching a sample piece transfer mechanism to the processed sample piece to extract and separate the sample piece from the wafer; attaching the sample piece to a carrier on a sample piece holder mounted on a sample piece holder stage that is tiltable and rotatable, such that the observation surface is parallel to a surface of the carrier; tilting the sample piece holder stage such that the observation surface is parallel to an optical axis of the ion beam; rotating the sample piece holder stage such that the observation surface intersects a tilt axis of a stage on which the sample piece holder stage is mounted; tilting the stage around the tilt axis such that an incident angle of the ion beam on the observation surface varies; processing the observation surface of the sample piece or a back surface of the observation surface by irradiation with the ion beam to thin the sample piece; changing a tilt of the sample piece holder stage to adjust an incident angle of the ion beam on the observation surface or the back surface such that the observation surface and the back surface are processed to be in parallel; and rotating the sample piece holder stage such that the observation surface or the back surface processed by the ion beam is observable by irradiation with an electron beam, and observing a processing state of the observation surface or the back surface.

### Advantageous Effects of Invention

According to an embodiment, the posture of the sample piece holder on which a plurality of carriers can be mounted can be controlled with respect to the wafer stage by a test piece holder stage having a plurality of drive shafts, and the sample piece holder can be transported independently of the wafer stage.

### BRIEF DESCRIPTION OF DRAWINGS

FIG. 1 is a diagram illustrating a configuration of a test system according to an embodiment.

FIG. 2 is a flowchart illustrating an outline of a test process in the test system.

FIG. 3 is a diagram illustrating a configuration of a charged particle beam device.

FIG. 4 is an appearance perspective view of a wafer stage and a sub stage.

FIG. 5 is an appearance perspective view of the sub stage.

FIG. 6 is an appearance perspective view of a holder.

FIG. 7 is a diagram illustrating a structural example of a carrier.

FIG. 8 is a diagram schematically illustrating a structure of a formed sample piece.

FIG. 9 is a diagram illustrating a process of transferring the sample piece onto the carrier.

FIG. 10 is a flowchart illustrating processes when the charged particle beam device performs a first operation.

FIG. 11 is a diagram illustrating an appearance of the sub stage, the holder, and the carrier during cross-sectional automatic sampling.

FIG. 12 is a flowchart illustrating a transfer process during the cross-sectional automatic sampling.

FIG. 13 is a diagram illustrating the appearance of the sub stage, the holder, and the carrier during planar automatic sampling.

FIG. 14 is a flowchart illustrating a transfer process during the planar automatic sampling.

FIG. 15 is a flowchart illustrating processes of a second operation when a first method is performed in a finishing process.

FIG. 16 is a flowchart illustrating a process of the second operation when a second method is performed in the finishing process.

FIG. 17 is a diagram schematically illustrating a relation between an ion beam and the sample piece in the first process of the finishing process.

FIG. 18 is a flowchart illustrating the first process of the finishing process.

FIG. 19 is a diagram schematically illustrating an appearance of an observation surface of the sample piece.

FIG. 20 is a diagram schematically illustrating the appearance of the sub stage, the holder, and the carrier mounted on the holder when the second process of the finishing process is performed.

FIG. 21 is a diagram schematically illustrating the relation between the ion beam and the sample piece in the second process of the finishing process.

FIG. 22 is a diagram schematically illustrating a positional relation between the sample piece and a needle during posture control automatic sampling.

FIG. 23 is a diagram schematically illustrating the appearance of the sub stage, the holder, and the carrier during the posture control automatic sampling.

FIG. 24 is a flowchart illustrating a transfer process during the posture control automatic sampling.

### DESCRIPTION OF EMBODIMENTS

Hereinafter, embodiments of the present disclosure will be described in detail with reference to the drawings. In the drawings, the same components are denoted by the same reference numerals in principle, and repeated description thereof is omitted. In order to facilitate understanding of the invention, expressions of components in the drawings may not represent the actual position, size, shape, range, and the like.

For the sake of description, in the case of describing the process executed by a program, a program, a function, a processing unit, and the like may be described as a main body, but a main body of hardware thereof is a processor, or a controller, a device, a computer, a system or the like implemented with a processor. The computer executes processing according to a program read onto a memory by a processor while appropriately using resources such as a memory and a communication interface. Accordingly, a predetermined function, processing unit, and the like are implemented. The processor is implemented with, for example, a semiconductor device such as a CPU or a GPU. The processor is implemented by a device or a circuit capable of performing a predetermined calculation. A process can be executed not only by a software program process but also by a dedicated circuit. The dedicated circuit may be an FPGA, an ASIC, a CPLD, or the like.

The program may be installed as data in a target computer in advance, or may be distributed as data from a program source to a target computer. The program source may be a program distribution server on a communication network, or may be a non-transitory computer-readable storage medium (for example, memory card). The program may include a plurality of modules. The computer system may include a plurality of devices. The computer system may be implemented as a cloud computing system, an IOT system, or the like. The various kinds of data and information are configured with a structure such as a table or a list, but are not limited thereto.

### Embodiments

### [Overall Configuration of System]

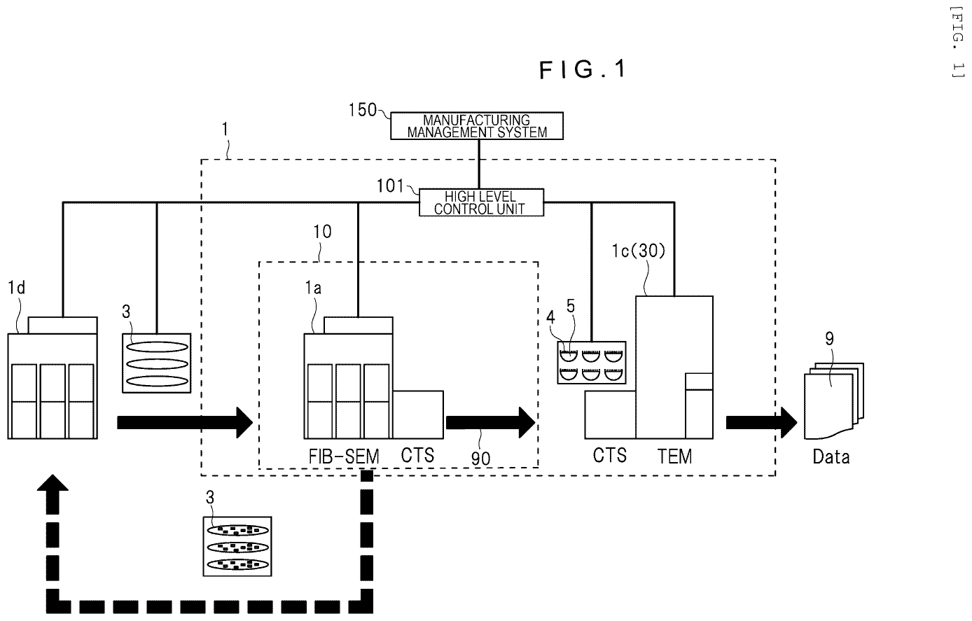

Hereinafter, a charged particle beam device according to an embodiment of the present disclosure and a test system including the charged particle beam device will be described with reference to the drawings. FIG. 1 is a schematic diagram illustrating a schematic configuration of a test system 1 according to an embodiment.

The test system 1 includes a sample piece production mechanism 1a, a sample piece observation mechanism 1c, and a high level control unit 101 as a control mechanism. As illustrated in FIG. 1, there is a charged particle beam device 10 as the sample piece production mechanism 1a. The charged particle beam device 10 as the sample piece production mechanism 1a is, for example, a FIB-SEM device. The sample piece observation mechanism 1c is, for example, a sample piece observation device 30 such as a TEM device.

The high level control unit 101 as a control mechanism controls, for example, each controller which is a control unit provided for each device. The controller of each device manages its own information and controls its own process operation. The controllers may be built in respective devices or may be externally connected. The controllers of the devices may communicate with each other as appropriate. The controllers of the respective devices may be configured to control the corresponding devices while cooperating with each other through communication.

The test system 1 receives a test instruction and test target portion information from a manufacturing management system 150 of a semiconductor manufacturing plant. The test system 1 receives, by transport, a wafer 3, which is a sample as a test target, from a semiconductor manufacturing line 1d of the semiconductor manufacturing plant. The transported wafer 3 is set in the charged particle beam device 10. The wafer 3 is transported, by a predetermined transport mechanism, between the semiconductor manufacturing line 1d and the charged particle beam device 10 of the test system 1. For example, FOUP, which is a container storing the wafer 3 is transported by an automatic transport system or manual transport by an operator.

The FIB-SEM device, which is the charged particle beam device 10, forms and produces a sample piece 4 by thinning a designated portion (site) of the transported wafer 3. The charged particle beam device 10 takes out the formed and produced sample piece 4 from the wafer 3, and transfers the sample piece 4 onto a carrier (LC: lamella carrier) 5. The TEM device, which is the sample piece observation device 30, observes and analyzes a cross section or a plane of the sample piece 4 on the carrier 5, and generates and outputs data 9 and the like as a result.

Various kinds of data and information are appropriately exchanged by communication between the devices of the test system 1 via the high level control unit 101. The various kinds of data and information include, for example, data indicating a test target position on a surface of the wafer 3, data indicating a position where the sample piece 4 is successfully created, and data indicating a position of the sample piece 4 mounted on the carrier 5. The data 9 as a test result includes a detection signal related to secondary electrons generated from the sample piece 4 irradiated with the beam, an image obtained based on the detection signal, data obtained as a result of processing the image, data related to X-rays generated from the sample piece 4, and the like.

The test system 1 performs, in a shared manner among the devices, a process operation of producing the sample piece 4 at a designated position of the designated wafer 3 and transferring the sample piece 4 onto a designated position on the designated carrier 5, and grasps information such as such a process operation, a state, and a position in terms of control. Then, the test system 1 outputs the test result of the sample piece 4 as the data 9.

Between the charged particle beam device 10 and the sample piece observation device 30, the sample piece 4 is transported by the transport mechanism 90. For example, the carrier 5 onto which the sample piece 4 is transferred is transported by an automatic transport system. It is also possible to transport and return the wafer 3 from the charged particle beam device 10 to the semiconductor manufacturing line 1d by a transport mechanism (not illustrated). FOUP, the carrier 5, or the like is used during various types of transport. The FOUP is a container filled with an inert gas such as nitrogen, and the wafer 3 or the like may be taken into and out of the container and stored therein.

The wafer 3 used in the embodiment includes a semiconductor substrate in which a p-type or n-type impurity region is formed, a semiconductor element such as a transistor formed on the semiconductor substrate, a wiring layer formed on the semiconductor element, and the like. The sample piece 4 is a portion formed on a part of the wafer 3 and taken out. Therefore, the sample piece 4 similarly includes structures of the semiconductor substrate, the semiconductor element, the wiring layer, and the like of the wafer 3. In the embodiment, the test of the sample piece 4 of the wafer 3 mainly used in the semiconductor manufacturing line is targeted, but the present invention is not limited thereto, and the sample may be a structure used in other than the semiconductor technology.

### [Process Flow of Test System]

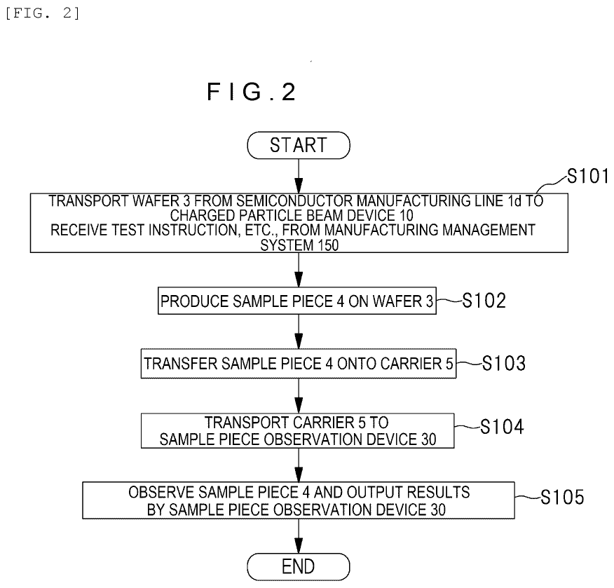

FIG. 2 is a flowchart illustrating a process flow of the test system 1. Each process illustrated in the flowchart of FIG. 2 is preferably automatically executed and controlled by the high level control unit 101, but a part of the process may be manually controlled. For example, in each step described below, an operator may press a start button at the start of the process of the device.

In step S101, a test target, that is, the FOUP in which the wafer 3 to be subjected to the cross-sectional analysis or the surface analysis is stored is transported from the semiconductor manufacturing line 1d to the charged particle beam device 10 through the transport mechanism. The charged particle beam device 10 receives the FOUP and places the wafer 3 on the stage. At this time, the high level control unit 101 of the charged particle beam device 10 acquires data and information such as test target portion information and a test instruction of the wafer 3 from the manufacturing management system 150.

In step S102, the high level control unit 101 causes the FIB-SEM device included in the charged particle beam device 10 to perform a process operation of thinning for forming and producing one or more sample pieces 4 on the wafer 3. The charged particle beam device 10 positions a field of view at the test target position (site) of the wafer 3 by moving the stage, based on the information received from the manufacturing management system 150. Then, the charged particle beam device 10 forms the sample piece 4 by irradiating the test target position with a beam which is an FIB.

In step S103, the high level control unit 101 causes the charged particle beam device 10 to perform a transfer process of transferring, onto the carrier 5, the sample piece 4 formed on the wafer 3. In step S104, the high level control unit 101 causes the transport mechanism 90 to perform a transport process of transporting the carrier 5 on which the sample piece 4 is mounted from the charged particle beam device 10 to the sample piece observation device 30. In step S105, the high level control unit 101 causes the TEM device included in the sample piece observation device 30 to perform cross-sectional observation or planar observation by using a TEM image. Results of the analysis and test performed through the cross-sectional observation or the planar observation are stored and output as the data 9.

### [Configuration of Charged Particle Beam Device]

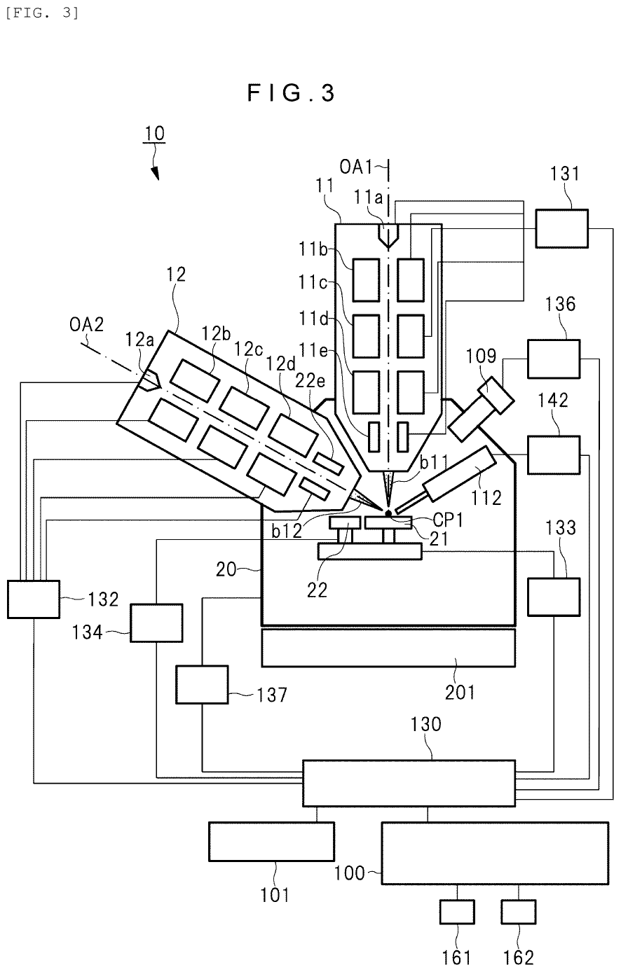

FIG. 3 is a schematic diagram illustrating a schematic configuration of the charged particle beam device 10. The charged particle beam device 10 includes a sample chamber 20, an ion beam column 11, an ion beam column controller 131, an electron beam column 12, an electron beam column controller 132, a wafer stage 21, a wafer stage controller 133, a sub stage 22, a sub stage controller 134, a needle 112, a needle controller 142, and the like. The charged particle beam device 10 includes a charged particle detector 109, a detector controller 136, a sample chamber controller 137, an integrated control unit 130, a computer system 100, and the like.

The charged particle beam device 10 includes a wafer loading mechanism (not illustrated). The wafer loading mechanism is a mechanism that loads the wafer 3 in the FOUP into the sample chamber 20 and unloads the wafer 3 in the sample chamber 20 into the FOUP.

The ion beam column 11, the electron beam column 12, the wafer stage 21, the sub stage 22, the needle 112, and the like are diposed in the sample chamber 20.

In the ion beam column 11, an optical axis OA1 (indicated by one-dot chain) is disposed along a vertical direction. In the electron beam column 12, an optical axis OA2 (indicated by one-dot chain) is disposed along a direction tilted relative to the optical axis OAl of the ion beam column 11. An ion beam b11, which is an FIB, is emitted from the ion beam column 11 toward a cross point CP1, and an electron beam b12 is emitted from the electron beam column 12 toward the cross point CP1. The ion beam b11 emitted from the ion beam column 11 and the electron beam b12 emitted from the electron beam column 12 are focused at the cross point CP1 which is an intersection of the respective optical axes. In this example, the optical axis of the electron beam column 12 is tilted relative to the optical axis of the ion beam column 11, but the present invention is not limited to such a configuration.

The ion beam column 11 includes components necessary as an FIB device, such as an ion source 11a for generating the ion beam b11, lenses 11b and 11c for focusing the ion beam b11, an objective lens 11d, and a deflector 11e for scanning the ion beam b11. That is, the ion beam column 11 is a charged particle beam column that emits a charged particle beam.

The electron beam column 12 includes components necessary as a SEM device, such as an electron source 12a for generating the electron beam b12, lenses 12b and 12c for focusing the electron beam b12, an objective lens 12d, and a deflector 12e for scanning the electron beam b12. That is, the electron beam column 12 is a charged particle beam column that emits a charged particle beam.

The wafer stage 21 is a moving stage on which the wafer 3 as a sample may be placed. The sub stage 22 is a moving stage on which the sample piece 4 or the carrier 5 may be placed. Details of the wafer stage 21 and the sub stage 22 will be described later. The wafer stage 21, the sub stage 22, and the like are capable of planar movement and rotational movement. The integrated control unit 130 controls the movement of the wafer stage 21 via the wafer stage controller 133 to position the wafer stage 21 so that a target portion (for example, portion where sample piece 4 is formed) on the surface of the wafer 3 can be irradiated with a beam. The integrated control unit 130 controls the movement of the sub stage 22 via the sub stage controller 134 to control the posture of the carrier 5 mounted on the sub stage 22.

The charged particle detector 109 detects, as a detection signal, charged particles generated when the sample is irradiated with the ion beam b11 and charged particles generated when the sample is irradiated with the electron beam b12. The detector controller 136 performs an arithmetic process on the detection signal of the charged particle detector 109 to form an image. The detector controller 136 includes an arithmetic processing unit implemented by a circuit or a program process.

The sample chamber 20 may include, as other types of detectors, an X-ray detector and a backscattered electron detector that detect backscattered electrons generated from the sample.

The needle 112 is provided inside the sample chamber 20 to be able to reach the cross point CP1. The needle 112 is controlled and driven by the needle controller 142 to function as a sample piece transfer mechanism that holds the sample piece 4 separated and extracted (lifted out) from the wafer 3 and transports and transfers the sample piece 4 onto the carrier 5. In addition, since the needle 112 can perform planar movement, vertical movement, and rotational movement, the posture of the sample piece 4 may be freely changed when the needle 112 holds the sample piece 4.

The sample chamber 20 includes, as other components, a gas supply unit (not illustrated) that supplies a gas used for etching or deposition. A degree of vacuum of the sample chamber 20 is controlled by the sample chamber controller 137. The sample chamber 20 may be provided on a vibration-proof table 201 in order to prevent vibration. In addition to the above-described configurations, a decompression device for evacuation, a cold trap, an optical microscope, or the like may be provided inside the sample chamber 20.

The charged particle beam device 10 is not limited to the FIB-SEM device as described above, and a FIB device without a SEM mechanism may be applied, or a FIB device including an optical microscope instead of a SEM mechanism may be applied.

The integrated control unit 130 controls the entire charged particle beam device 10 and each unit. The integrated control unit 130 is electrically connected to controllers of respective units, such as the wafer stage controller 133 and the sub stage controller 134, and may communicate with each other. The integrated control unit 130 controls controllers and the like of the respective units by a control signal. The plurality of controllers may be integrated as one controller. Each controller may be implemented by a computer system, a dedicated circuit, or the like. The computer system 100 is connected to the integrated control unit 130. The integrated control unit 130 controls the entire charged particle beam device 10 and the operation of each unit according to an instruction or the like from the computer system 100.

The computer system 100 provides a user interface including a GUI to a user who uses the charged particle beam device 10, and receives input of various instructions, settings, and the like by the user. An input device 162, an output device 161, a storage device, and the like are built in or externally connected to the computer system 100. Examples of the input device 162 include a keyboard, a mouse, a touch panel, and a microphone. Examples of the output device 161 include a display, a printer, a speaker, and a lamp. A screen with a GUI is displayed on the display. An image captured by the charged particle beam device 10, setting information, user instruction information, and the like are displayed on the screen.

A user such as an operator can check various kinds of information, images, and the like on the screen displayed on the display. The user inputs various instructions and settings to the screen by using a keyboard or the like. The computer system 100 transmits an instruction or the like to the integrated control unit 130 based on the input instruction, setting, or the like. The integrated control unit 130 and the computer system 100 may be integrated.

### [Wafer Stage 21 and Sub Stage 22]

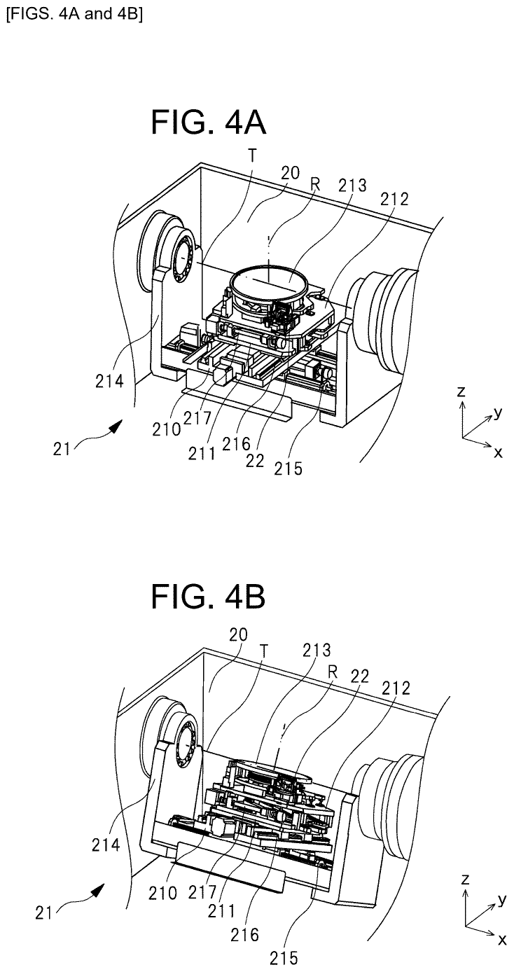

(A) of FIG. 4 and (B) of FIG. 4 are appearance perspective views of the wafer stage 21 and the sub stage 22 provided in the sample chamber 20. (A) of FIG. 4 illustrates a case where a rotation angle about a T-axis described later is 0°, and (B) of FIG. 4 illustrates a case where the rotation angle about the T-axis is 20°.

Hereinafter, as illustrated in FIG. 4, an orthogonal coordinate system including an x-axis, a y-axis, and a z-axis will be described. The z-axis is set along the vertical direction, and an upper side of the sample chamber 20, that is, an upper side of the charged particle beam device 10 is located on a z-axis positive side. The x-axis is set in a direction orthogonal to the z-axis, and the y-axis is set in a direction orthogonal to the x-axis and the z-axis. By: setting the orthogonal coordinate system, it can be said that the ion beam column 11 described above emits the ion beam b11 from the z-axis positive side toward a z-axis negative side. That is, the optical axis OAl of the ion beam column 11 is parallel to the z-axis. The electron beam column 12 emits the electron beam b12 from the z-axis positive side and a y-axis positive side toward the z-axis negative side and a y-axis negative side. That is, the optical axis OA2 of the electron beam column 12 is tilted relative to an xy plane. The postures of the wafer stage 21 and the sub stage 22 are controlled by the wafer stage controller 133 or the sub stage controller 134 such that the wafer stage 21 and the sub stage 22 may be processed and observed by the ion beam b11 and the electron beam b12 emitted in the above directions.

### [Wafer Stage 21]

The wafer stage 21 is movable with the wafer 3 placed thereon. Specifically, the wafer stage 21 includes an x-base 210, a y-base 211, a z-base 212, a rotation base 213, and a support mechanism 214. As illustrated in (A) of FIG. 4, the x-base 210, the y-base 211, the z-base 212, and the rotation base 213 are provided in the sample chamber 20 in the above-described order from a lower side, that is, the z-axis negative side, when the rotation angle about the T-axis described later is 0°.

The x-base 210 is a plate-shaped member having a long side extending in a y-axis direction. An x-axis drive mechanism 215 including, for example, a motor, a ball screw, and a guide member extending along the x-axis is provided below the x-base 210. When the motor of the x-axis drive mechanism 215 is driven, the ball screw rotates, and the x-base 210 moves along the x-axis, which is a first direction. When the x-base 210 moves along the x-axis, the y-base 211, the z-base 212, and the rotation base 213 provided above the x-base 210 also move along the x-axis, which is the first direction, together with the x-base 210.

The drive of the x-axis drive mechanism 215 is controlled by the integrated control unit 130 via the wafer stage controller 133. Movement of the x-base 210 by the x-axis drive mechanism 215 is controlled by, for example, encoder control or linear scale control, and the x-base 210 is positioned with high accuracy. A movable range of x-base 210 is, for example, 0 mm to 327 mm in which the wafer 3 having a size of 300 mm is accommodated. A y-axis drive mechanism 216 for moving the y-base 211 is provided on an upper surface of the x-base 210.

The y-base 211 is a plate-shaped member and is provided on an upper surface side of the x-base 210. More specifically, the y-base 211 is provided on the y-axis drive mechanism 216 provided on the upper surface of the x-base 210. The y-axis drive mechanism 216 includes, for example, a motor, a ball screw, and a guide member extending along a second direction intersecting (orthogonal to) the x-axis. The second direction is the y-axis direction when the rotation angle about the T-axis described later is 0° (see (A) of FIG. 4). When the motor of the y-axis drive mechanism 216 is driven, the ball screw rotates, and the y-base 211 moves along the second direction. When the y-base 211 moves along the second direction, the z-base 212 and the rotation base 213 provided above the y-base 211 also move along the second direction together with the y-base 211. That is, the y-base 211 is movable in the first direction and the second direction.

The drive of the y-axis drive mechanism 216 is controlled by the integrated control unit 130 via the wafer stage controller 133. Movement of the y-base 211 by the y-axis drive mechanism 216 is controlled by, for example, encoder control or linear scale control, and the y-base 211 is positioned with high accuracy. A movable range of the y-base 211 is, for example, 0 mm to 327 mm in which the wafer 3 having a size of 300 mm is accommodated. A z-axis drive mechanism 217 that moves the z-base 212 is provided on an upper surface side of the y-base 211.

The z-base 212 is a plate-shaped member and is provided on the upper surface side with respect to the y-base 211. More specifically, the z-base 212 is provided on the z-axis drive mechanism 217 provided on an upper surface of the y-base 211. The z-axis drive mechanism 217 includes, for example, a motor, a ball screw, and a wedge-shaped guide member extending along the x-axis and tilted relative to the y-base 211. When the motor of the z-axis drive mechanism 217 is driven, the ball screw rotates, and the z-base 212 moves along a tilted surface of the wedge-shaped guide member. As a result, the z-base 212 moves along a direction orthogonal to the y-base 211, that is, a third direction orthogonal to the first direction and the second direction. That is, the z-base 212 is movable in the first direction, the second direction, and the third direction. The third direction is the z-axis direction when the rotation angle about the T-axis described later is 0° (see (A) of FIG. 4). When the z-base 212 moves along the third direction, the rotation base 213 provided above the z-base 212 also moves along the third direction together with the z-base 212. That is, as illustrated in (A) of FIG. 4, when the rotation angle about the T-axis is 0°, the z-base 212 moves along the z-axis, and together with this movement, the rotation base 213 also moves along the z-axis.

The drive of the z-axis drive mechanism 217 is controlled by the integrated control unit 130 via the wafer stage controller 133. The movement of the z-base 212 by the z-axis drive mechanism 217 is controlled by, for example, encoder control or linear scale control, and the z-base 212 is positioned with high accuracy.

The rotation base 213 is provided on the z-base 212. The rotation base 213 is a placing table on which the wafer 3 is placed, and is disposed to be rotatable about an R-axis which is a first axis intersecting (orthogonal to) the z-base 212. The R-axis, which is the first axis, is parallel to the z-axis when the rotation angle about the T-axis described later is 0° (see (A) of FIG. 4). The rotation base 213 is rotated by a drive mechanism of which the drive is controlled by the integrated control unit 130 via the wafer stage controller 133. In this case, for example, when a ceramic ring is rotated by an ultrasonic motor, the rotation base 213 is rotated and may be positioned in a rotation direction with high accuracy. The rotation base 213 has an electrostatic chuck. The wafer 3 is placed on the rotation base 213 by being attracted by an electrostatic force of the electrostatic chuck.

The support mechanism 214 is rotatably held, via gears or the like, on two side walls of the sample chamber 20 intersecting the x-axis. The support mechanism 214 rotates about the T-axis, which is a second axis parallel to the x-axis, by synchronously driving the gears provided on two side surfaces of the sample chamber 20. The support mechanism 214 supports the x-axis drive mechanism 215 provided on a lower surface side of the x-base 210 to integrally support the x-base 210, the y-base 211, the z-base 212, and the rotation base 213, which are provided above the x-axis drive mechanism 215. Therefore, when the support mechanism 214 rotates about the T-axis, the rotation base 213 on which the wafer 3 is placed may be tilted relative to the xy plane, for example, as illustrated in (B) of FIG. 4. In other words, the T-axis is a tilt axis for tilting, relative to the xy plane, the wafer stage 21 on which the wafer 3 is placed.

### [Sub Stage 22]

The sub stage 22 is a sample piece holder stage on which a holder 6 described later is detachably mounted and which is movable independently of the wafer stage 21. Specifically, as illustrated in (A) of FIG. 4 and (B) of FIG. 4, the sub stage 22 is provided on the z-base 212 of the wafer stage 21 described above. Therefore, when the wafer stage 21 moves along a first direction axis, the second direction, and the third direction as described above, the sub stage 22 also moves along the first direction, the second direction, and the third direction together with the wafer stage 21. When the wafer stage 21 rotates about the T-axis and tilts relative to the xy plane, the sub stage 22 also rotates about the T-axis together with the wafer stage 21 and tilts relative to the xy plane.

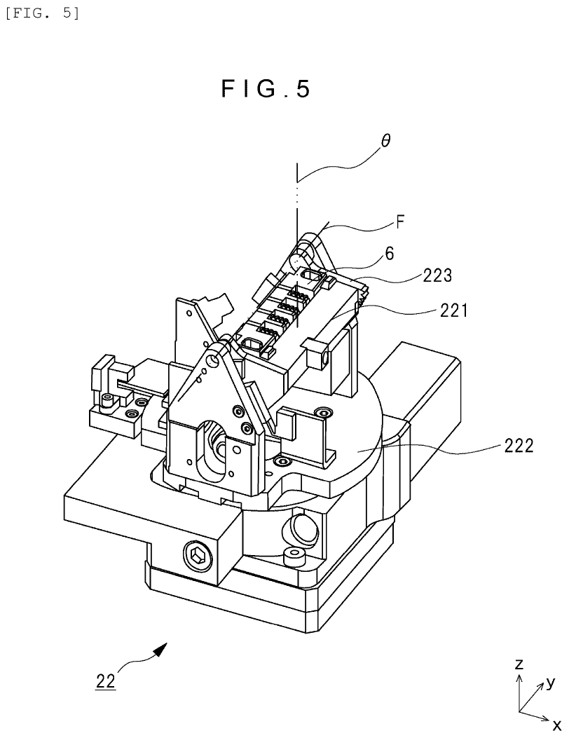

FIG. 5 is an appearance perspective view of the sub stage 22. Note that FIG. 5 illustrates the sub stage 22 when the rotation angle about the T-axis is 0°. The sub stage 22 includes a mounting portion 221 on which the holder 6 is detachably mounted (loaded), the carrier 5 being mounted on the holder 6, a mounting support portion 222 that supports the mounting portion 221, and a tilt mechanism 223. The mounting portion 221 has a placement surface (not illustrated), and the holder 6 transported by the transport mechanism 90 is placed and mounted on the placement surface. The mounting support portion 222 is attached to the z-base 212 to be rotatable about a θ-axis which is a third axis intersecting (orthogonal to) the z-base 212. The mounting support portion 222 is rotated by a drive mechanism controlled by the sub stage controller 134.

The tilt mechanism 223 is an arm member fixed to the mounting portion 221, and is attached to the mounting support portion 222 to be rotatable about an F-axis which is a fourth axis intersecting (orthogonal to) the θ-axis at an end portion on one side, and a gear is formed at an end portion on the other side. Therefore, when the driving force of the drive mechanism controlled by the sub stage controller 134 is transmitted via the gear, the tilt mechanism 223 rotates about the F-axis. As the tilt mechanism 223 rotates, the mounting portion 221 fixed to the tilt mechanism 223 rotates about the F-axis. As a result, the mounting portion 221 and the holder 6 are tilted relative to a surface parallel to the z-base 212.

When the mounting support portion 222 rotates about the θ-axis by the driving force of the drive mechanism controlled by the sub stage controller 134, the tilt mechanism 223 and the mounting portion 221 rotate about the θ-axis with the rotation of the mounting support portion 222. As a result, the mounting portion 221 rotates about an axis orthogonal to the z-base 212 in a plane parallel to the z-base 212. In FIG. 5, the θ-axis and the z-axis are parallel to each other, and the F-axis and the y-axis are parallel to each other.

Since the sub stage 22 has the above configuration, the sub stage 22 moves (rotates) about the e-axis and moves (tilts) about the F-axis independently of the wafer stage 21. Accordingly, the holder 6 and the carrier 5 mounted on the holder 6 can also rotate about the θ-axis independently of the wafer stage 21 and tilt about the F-axis. The carrier 5 mounted on the holder 6 attached to the mounting portion 221 and the wafer 3 placed on the rotation base 213 are designed such that heights, that is, distances along the third direction from the z-base 212 are equal.

### [Holder 6]

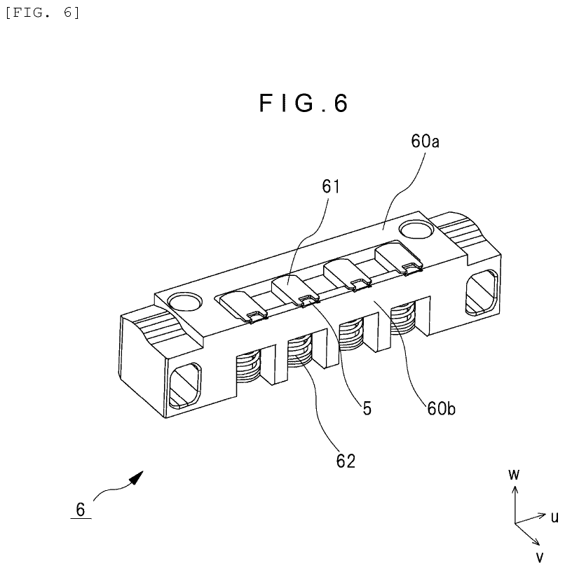

The holder 6 is a sample piece holder on which the plurality of carriers 5 are mounted, and is detachably attached to the sub stage 22 which is a sample piece holder stage. FIG. 6 is an appearance perspective view of the holder 6. The holder 6 has a columnar shape. Hereinafter, as illustrated in FIG. 6, an orthogonal coordinate system including a u-axis, a v-axis, and a w-axis will be described. The u-axis is an axis set along a longitudinal direction of the holder 6. The v-axis is an axis orthogonal to the u-axis and set along a lateral direction of the holder 6. The w-axis is an axis orthogonal to the u-axis and the v-axis and set along a height direction of the holder 6.

A carrier holding portion 61 for holding the mounted carriers 5 is provided on a surface 60a on a w-axis positive side of the holder 6. The carrier holding portion 61 is a plate-shaped member, and a biasing force toward a w-axis negative direction is applied by a biasing portion 62, such as a coil spring, provided on a w-axis negative side. The carrier 5 is mounted on the holder 6 by sandwiching the carrier 5 between the surface 60a and a surface on the w-axis negative side of the carrier holding portion 61. As illustrated in FIG. 6, the carrier 5 held and mounted on the carrier holding portion 61 protrudes to a v-axis positive side from the surface 60b on the v-axis positive side of the holder 6. FIG. 6 illustrates a case where the holder 6 includes four carrier holding portions 61, and the number of carrier holding portions 61 may be three or less, or may be five or more.

The holder 6 is mounted on the mounting portion 221 of the sub stage 22 described above. As described above, since the mounting portion 221 on which the holder 6 is mounted is fixed to the tilt mechanism 223, it can be said that the holder 6 is detachably mounted on the sub stage 22 independently of the tilt mechanism 223.

When the surface 60a of the holder 6 attached to the sub stage 22 described above is parallel to the z-base 212 on the z-axis positive side, the rotation angle of the sub stage 22 about the F-axis is 0°. The rotation angle of the sub stage 22 about the θ-axis when a positive direction and a negative direction of the u-axis of the holder 6 attached to the sub stage 22 coincide with a positive direction and a negative direction of the y-axis is set to 0°. Therefore, FIG. 5 described above illustrates a case where the rotation angle of the sub stage 22 about the θ-axis is 0°and the rotation angle about the F-axis is 90°.

### [Carrier 5]

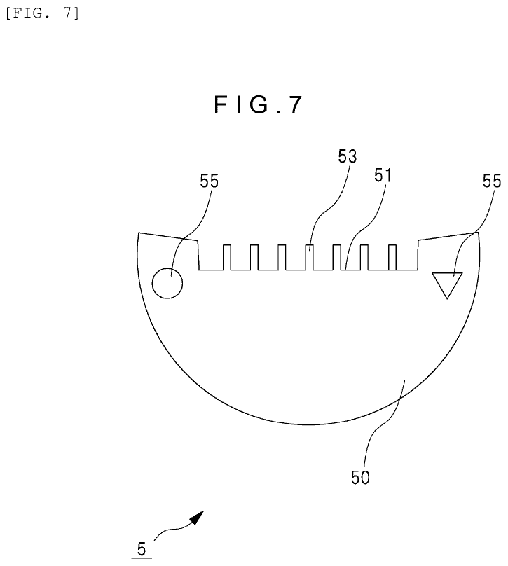

FIG. 7 is a diagram illustrating a structural example of the carrier 5. The carrier 5 may be referred to as a lamellar grid, a TEM mesh, or the like. The carrier 5 includes a half-moon type base body 50 and a plurality of pillars 53 protruding from a linear portion 51 in a surface of the base body 50. Each pillar 53 is a sample piece support portion having a structure capable of mounting and holding the sample piece 4.

Both end portions of the base body 50 where the pillar 53 is not provided (circumferential portions in planar view of upper surface of carrier 5) are provided with marks 55 implemented by holes penetrating the base body 50. The marks 55 are provided as marks having different shapes, and here, the marks 55 having a circular shape and a triangular shape are exemplified. The marks 55 facilitate identification of the front and rear of the carrier 5. When the position of the pillar 53 onto which the sample piece 4 is to be transferred is determined, a desired pillar 53 can be searched with reference to the mark 55, and the transfer position can be easily specified.

### [Operation of Charged Particle Beam Device]

The operation of the charged particle beam device 10 having the above configuration will be described. The charged particle beam device 10 performs a first operation of forming, producing, and transferring (sampling) the sample piece 4 from the wafer 3 and observing the sampled sample piece 4, a second operation of performing finishing on the sampled sample piece 4, or a third operation of performing only sampling of the sample piece 4. Hereinafter, each of the first operation, the second operation, and the third operation will be described.

### [First Operation]

In the charged particle beam device 10, after a preparation process is performed, a processing process, a transfer process, and an observation process included in the production and observation method are performed as the first operation.

### [Preparation Process]

The integrated control unit 130 performs the preparation process as advance preparation for a process of forming and producing the sample piece 4. The preparation process is a process corresponding to step S101 illustrated in FIG. 2 described above. Specifically, the wafer 3 is loaded onto the rotation base 213 of the wafer stage 21, and the holder 6 on which the carrier 5 is mounted is loaded onto the sub stage 22. The ion beam b11 and the electron beam b12 emitted from the ion beam column 11 and the electron beam column 12, respectively, are adjusted.

The integrated control unit 130 controls the wafer stage controller 133 to adjust positions of the x-axis, the y-axis, the z-axis, the T-axis, and the R-axis of the wafer stage 21, thereby performing alignment of the position of the wafer 3. Then, the integrated control unit 130 inputs, from the high level control unit 101, position data indicating a position where the sample piece 4 is formed and produced on the wafer 3. The integrated control unit 130 controls the wafer stage controller 133 to move the wafer stage 21 based on the input position data, and positions the formed and produced sample piece 4 at the cross point CP1.

### [Processing Process]

When the preparation process is completed, the integrated control unit 130 performs the processing process of processing the wafer 3 to form the sample piece 4. The processing process is a process corresponding to step S102 illustrated in FIG. 2 described above.

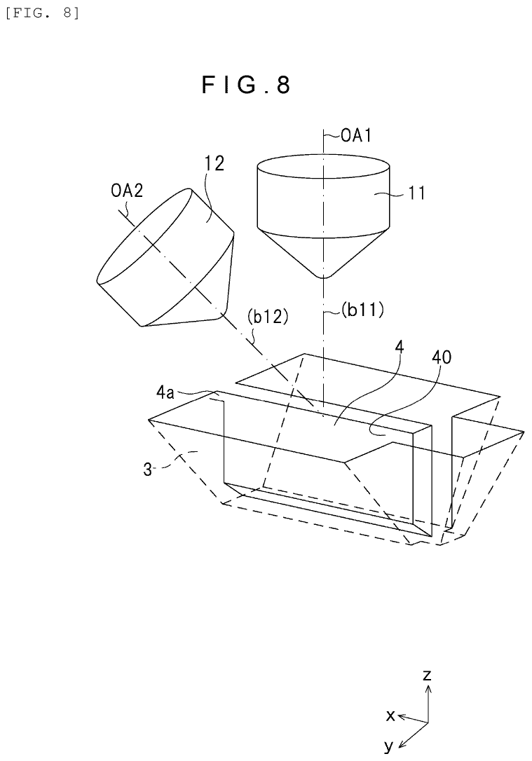

FIG. 8 is a diagram schematically illustrating a structure of the sample piece 4 formed and produced by the processing process. FIG. 8 illustrates the formed and produced sample piece 4 when a cross-sectional structure of the wafer 3 is observed (cross-sectional observation). In this case, the sample piece 4 is a thin piece having a width in the y-axis direction thinner than widths in the x-axis direction and the z-axis direction. In this case, the cross section of the wafer 3 becomes an observation surface 40 described later of the sample piece 4. When the sample piece 4 for observing the planar structure of the wafer 3 (planar observation) is formed and produced, the sample piece 4 may be a thin piece having a width in the z-axis direction thinner than the widths in the x-axis direction and the y-axis direction. In this case, the plane of the wafer 3 is an observation surface described later of the sample piece 4.

A protective film is formed on the wafer 3 based on the shape of the sample piece 4. In this case, a protective film is formed on the surface of the wafer 3 by pouring a protective film material such as carbon gas in a state where the position where the sample piece 4 is formed and produced is observed by irradiating the wafer 3 with the ion beam b11 from the ion beam column 11. The ion beam column 11 irradiates the wafer 3 outside the protective film with the ion beam b11 to etch a part of the wafer 3. Thus, the sample piece 4 is formed and produced.

As a result, in the processing process, the wafer 3 is irradiated with the ion beam b11 to process the sample piece 4 having the plane or cross section of the wafer 3 as an observation surface. At this time, the sample piece 4 is connected to the wafer 3 by a connection portion 4a. In other words, at this time, the connection portion 4a and the wafer 3 are integrated, and as described later, when the sample piece 4 is transferred onto the carrier 5 by the needle 112, the sample piece 4 is separated from the connection portion 4a.

### [Transfer Process]

In the transfer process, the sample piece 4 processed in the processing process is extracted and separated (lifted out) from the wafer 3 by attaching the needle 112, which is a sample piece transfer mechanism, to the sample piece 4. Then, the lifted out sample piece 4 is attached to the carrier 5 on the holder 6 mounted on the sub stage 22 such that the observation surface 40 of the sample piece 4 is parallel to the surface of the carrier 5. The process is a process corresponding to step S103 illustrated in FIG. 2, and is performed by an automatic microsampling method.

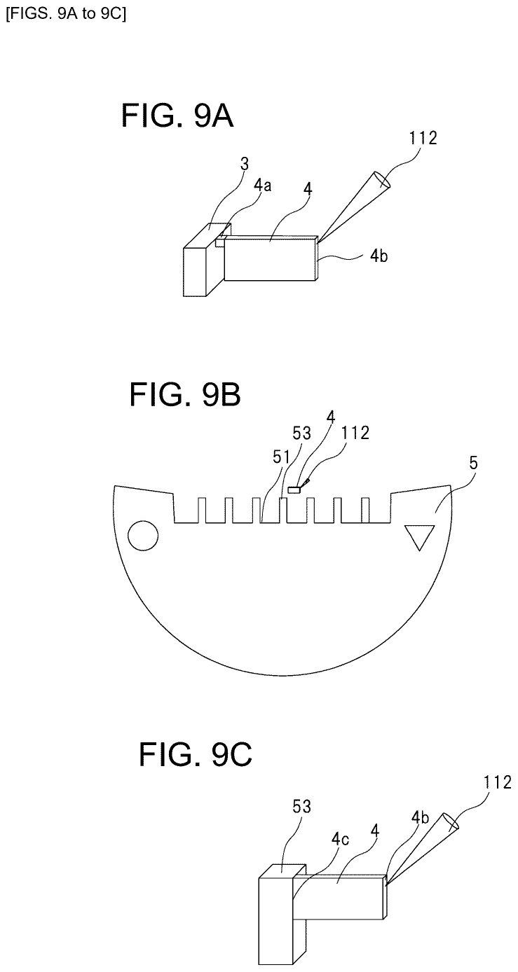

FIG. 9 is a diagram illustrating the transfer process. First, as illustrated in (A) of FIG. 9, the needle 112 is controlled by the needle controller 142 and approaches the sample piece 4. By performing deposition in the sample chamber 20, the needle 112 is bonded to a part of the sample piece 4. As illustrated in the drawing, the needle 112 is bonded to a side surface 4b of the sample piece 4 on a side opposite to the connection portion 4a. The ion beam column 11 performs etching by irradiating, with the ion beam b11, the connection portion 4a connecting the sample piece 4 and the wafer 3. Accordingly, the sample piece 4 is cut, extracted, and separated from the wafer 3.

Next, as illustrated in (B) of FIG. 9, the sample piece 4 held by the needle 112 is moved to the position of the pillar 53 on the carrier 5 by the movement of the needle 112 controlled by the needle controller 142. As described above, since the carrier 5 is mounted on the holder 6 attached to the sub stage 22, the carrier 5 is placed at a position different from the wafer 3. When the cross-sectional observation is performed, the sub stage 22 is driven to a position where both the rotation angles about the F-axis and the θ-axis are 90°. When the planar observation is performed, the sub stage 22 is driven to a position where the angles about the F-axis and the θ-axis are 0° and 90°, respectively. Then, the movement of the needle 112 is controlled by the needle controller 142, and the sample piece 4 approaches the position of the pillar 53. The operation of each unit in the transfer of the sample piece 4 onto the carrier 5 will be described in detail later.

As illustrated in (C) of FIG. 9, a side surface 4c on a side opposite to the side surface 4b where the sample piece 4 is connected to the needle 112 is close to the pillar 53. By performing deposition in the vicinity of the side surface 4c, the pillar 53 and the sample piece 4 are bonded. At this time, the observation surface 40 of the sample piece 4, which is a cross section or a plane of the wafer 3, is attached to be parallel to the surface of the carrier 5. Then, the ion beam column 11 performs etching by irradiating, with the ion beam b11, a portion of the side surface 4b where the sample piece 4 and the needle 112 are connected. Accordingly, the sample piece 4 is cut from the needle 112.

FIG. 9 illustrates a case where one sample piece 4 is supported on one pillar 53. However, the pillar 53 may be made high to support a plurality of sample pieces 4 by one pillar 53.

### [Observation Process]

In the observation process, the sub stage 22 is rotated about the θ-axis such that the observation surface 40 of the sample piece 4 may be irradiated with the electron beam b12 and may be observed. When the observation surface 40 of the sample piece 4 is observed, the sub stage 22 is rotated about the θ-axis such that a back surface of the observation surface 40 of the sample piece 4 may be irradiated with the electron beam b12 and may be observed. Specifically, when the sample piece 4 is transferred to be supported by the pillar 53 of the carrier 5 by the transfer process, the electron beam column 12 irradiates, with the electron beam b12, the observation surface 40 of the sample piece 4 supported by the pillar 53. For example, when the cross-sectional observation is performed, the sub stage 22 is controlled by the sub stage controller 134 and is driven to a position where the rotation angle about the θ-axis is 90°. That is, the observation surface 40 of the sample piece 4 transferred onto the carrier 5 faces the electron beam column 12.

The charged particle detector 109 detects charged particles generated from the observation surface 40 of the sample piece 4, and the detector controller 136 performs an arithmetic process on a detection signal included in the detected charged particles and images the detection signal. The structure and the like of the observation surface 40 of the sample piece 4 may be analyzed based on the image. When the charged particle beam device 10 includes an X-ray detector, the X-ray detector can detect X-rays generated from the observation surface 40 of the sample piece 4 and analyze substances or the like constituting the observation surface 40 of the sample piece 4.

When observing the back surface of the sample piece 4 on the side opposite to the observation surface 40 observed as described above, the sub stage 22 is controlled by the sub stage controller 134, and is driven to a position where the rotation angle about the θ-axis rotated by 180° about the θ-axis is −90°. That is, the back surface of the sample piece 4 faces the electron beam column 12. Then, the back surface of the sample piece 4 is irradiated with the electron beam b12 to perform the observation process, similarly to the case where the observation surface 40 of the sample piece 4 is observed. It is an example that the sub stage 22 is driven to the position where the rotation angle about the θ-axis is 90° or −90 ° described above. The rotation angle about the θ-axis can be set to any value according to the observation portion.

After the above-described process operation is performed for the specified number of sample pieces 4 by the charged particle beam device 10, the wafer 3 is removed (unloaded) from the rotation base 213 of the wafer stage 21, and the holder 6 on which the carrier 5 is mounted is removed (unloaded) from the sub stage 22.

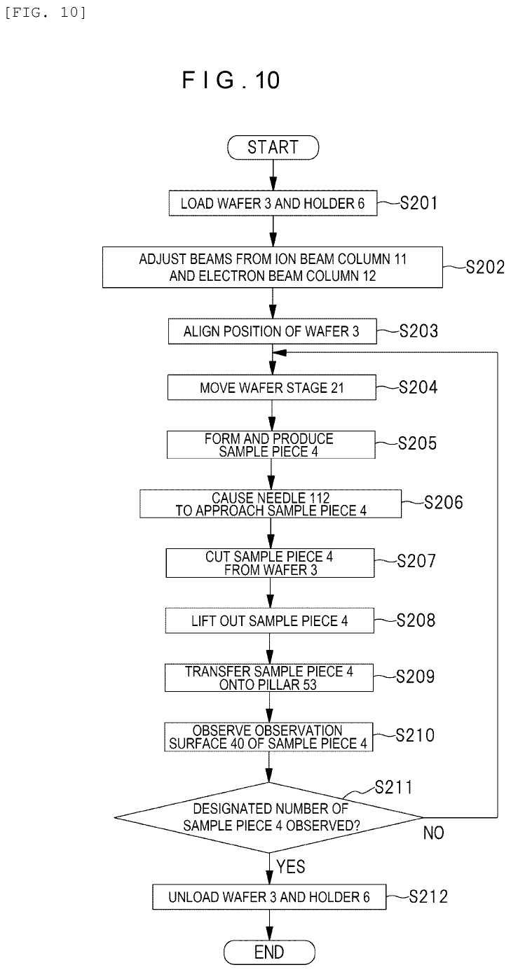

FIG. 10 is a flowchart illustrating an operation flow of the charged particle beam device 10. Each process illustrated in FIG. 10 is automatically executed and controlled by the integrated control unit 130.

In step S201, the integrated control unit 130 loads the wafer 3 onto the rotation base 213 of the wafer stage 21, and loads, onto the sub stage 22, the holder 6 on which the carrier 5 is mounted. In step S202, the integrated control unit 130 controls the ion beam column controller 131 and the electron beam column controller 132 to adjust the ion beam b11 and the electron beam b12 emitted from the ion beam column 11 and the electron beam column 12, respectively.

In step S203, the integrated control unit 130 controls the wafer stage controller 133 to drive the wafer stage 21 and align the position of the wafer 3. In step S204, the integrated control unit 130 controls the wafer stage controller 133 to move the wafer stage 21 based on the position data input from the high level control unit 101, and positions the formed sample piece 4 at the cross point CP1. The processes of steps S201 to S204 described above are the preparation processes.

In step S205, as the processing process, the integrated control unit 130 controls the ion beam column controller 131 to irradiate the wafer 3 with the ion beam b11 from the ion beam column 11. As described above, the ion beam column 11 forms and produces the sample piece 4 by irradiating, with the ion beam b11, the wafer 3 outside the protective film formed on the wafer 3 and etching a part of the wafer 3.

In step S206, the integrated control unit 130 controls the needle controller 142 to cause the needle 112 to approach the sample piece 4. The integrated control unit 130 causes the needle 112 to bond to a part of the sample piece 4 by deposition. In step S207, the integrated control unit 130 controls the ion beam column controller 131 to cause the ion beam column 11 to irradiate the connection portion 4a with the ion beam b11 for etching. Accordingly, the sample piece 4 is cut from the wafer 3. In step S208, the integrated control unit 130 controls the needle controller 142 to move the needle 112 and lift out the sample piece 4 from the wafer 3.

In step S209, the integrated control unit 130 controls the needle controller 142 to move the needle 112 to the position of the pillar 53 on the carrier 5. The integrated control unit 130 performs deposition in the vicinity of the side surface 4c of the sample piece 4 to bond the pillar 53 and the sample piece 4. Then, the integrated control unit 130 controls the ion beam column controller 131 to cause the ion beam column 11 to irradiate, with the ion beam b11, the portion 4d where the sample piece 4 and the needle 112 are connected, thereby performing etching. Accordingly, the sample piece 4 is cut from the needle 112, and the sample piece 4 is transferred onto the pillar 53, that is, the carrier 5. The processes of steps S206 to S209 described above is the transfer process.

In step S210, the integrated control unit 130 controls the electron beam column controller 132 to cause the electron beam column 12 to irradiate, with the electron beam b12, the observation surface 40 of the sample piece 4 supported by the pillar 53. Then, the integrated control unit 130 causes the charged particle detector 109 to detect charged particles generated from the observation surface 40 of the sample piece 4, and performs the observation process of performing an arithmetic process on a detection signal included in the charged particles and imaging the detection signal.

In step S211, it is determined whether the designated number of sample pieces 4 is formed and produced, transferred onto the carrier 5, and subjected to the observation process. When each process is performed on the designated number of sample pieces 4, the integrated control unit 130 makes an affirmative determination, and the process proceeds to step S212. When the number of sample pieces 4 subjected to each process described above does not reach the designated number, the integrated control unit 130 makes a negative determination, and the process returns to step S204.

In step S212, the integrated control unit 130 unloads the wafer 3 from the rotation base 213 of the wafer stage 21, unloads, from the sub stage 22, the holder 6 on which the carrier 5 is mounted, and ends the process.

### [Details of Transfer Process]

Details of step S209 in the above-described transfer process will be described. The rotation angles of the sub stage 22 about the F-axis and the θ-axis are different between the transfer process in the case where the cross-sectional observation is performed (cross-sectional automatic microsampling) and the transfer process in the case where planar observation is performed (planar automatic sampling). Hereinafter, the case where the cross-sectional automatic sampling is performed on the sample piece 4 and the case where the planar automatic sampling is performed will be separately described.

### [Transfer Process in Case Where Sample Piece is Subjected to Cross-Sectional Observation (Cross-Sectional Automatic Sampling)]

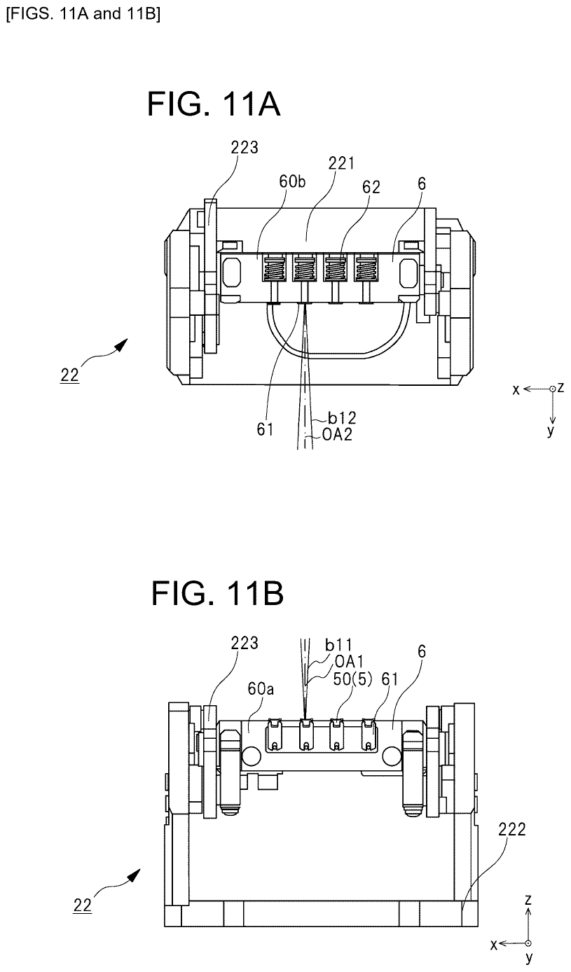

FIG. 11 is a diagram schematically illustrating the appearance of the sub stage 22, the holder 6 attached to the sub stage 22, and the carrier 5 mounted on the holder 6. (A) of FIG. 11 is the appearance of the sub stage 22, the holder 6, and the carrier 5 viewed from the z-axis positive side, and (B) of FIG. 11 is the appearance of the sub stage 22, the holder 6, and the carrier 5 viewed from the y-axis positive side.

As described above, in the case where the cross-sectional observation is performed, the sub stage 22 is driven to the position where the rotation angles about the F-axis and the θ-axis are both 90°. Therefore, as illustrated in (A) of FIG. 11 and (B) of FIG. 11, the surface of the base body 50 of the carrier 5 is parallel to a zx plane and faces the y-axis positive side, and the pillar 53 protrudes toward the z-axis positive side. In other words, the surface of the base body 50 of the carrier 5 faces the electron beam column 12.

In this state, the ion beam column 11 and the electron beam column 12 irradiate the carrier 5 with the ion beam b11 and the electron beam b12, respectively. During the irradiation with the ion beam b11 and the electron beam b12, the needle 112 is moved to a position where the needle 112 is not irradiated with the ion beam b11 and the electron beam b12, for example, a retracted position on the z-axis positive side.

The charged particles generated by the irradiation with the ion beam b11 are detected as a detection signal by the charged particle detector 109, and the detection signal is imaged by the detector controller 136. As illustrated in (B) of FIG. 11, the carrier 5 is irradiated with the ion beam b11 from the z-axis positive side. Therefore, the detector controller 136 generates an image (LC image) of the carrier 5 viewed from the z-axis positive side. The integrated control unit 130 detects, by using the image, presence or absence of positional deviation of the carrier 5 in an xy direction. When there is a positional deviation, the wafer stage controller 133 moves the z-base 212 along the x-axis and the y-axis to adjust the positional deviation of the sub stage 22.

The charged particles generated by the irradiation with the electron beam b12 are detected as a detection signal by the charged particle detector 109, and the detection signal is imaged by the detector controller 136. As illustrated in (B) of FIG. 11, the carrier 5 is irradiated with the electron beam b12 from the y-axis positive side. Therefore, the detector controller 136 generates an image (LC image) of the carrier 5 viewed from the y-axis positive side. The integrated control unit 130 detects, by using the image, presence or absence of a positional deviation of the carrier 5 in a zx direction. When there is a positional deviation, the wafer stage controller 133 moves the z-base 212 along the x-axis and the z-axis to adjust the positional deviation of the sub stage 22.

In addition, the integrated control unit 130 determines the position of the pillar 53 onto which the sample piece 4 is to be transferred, based on the LC image in the state viewed from the z-axis positive side and the LC image in the state viewed from the y-axis positive side. The needle controller 142 moves the needle 112 to the vicinity of the pillar 53 determined based on the LC image. At this time, the integrated control unit 130 calculates a movement amount of the needle 112 based on coordinates of the retracted position of the needle 112 and coordinates of the position of the pillar 53 determined based on the LC image. The needle controller 142 moves the needle 112 by the calculated movement amount.

In this state, the ion beam column 11 and the electron beam column 12 irradiate the sample piece 4 bonded to the needle 112 with the ion beam b11 and the electron beam b12, respectively. The charged particles generated by the irradiation with the ion beam b11 are detected as a detection signal by the charged particle detector 109, and the detection signal is imaged by the detector controller 136. That is, an image (needle image) of the sample piece 4 and the needle 112 viewed from the z-axis positive side is generated. The integrated control unit 130 specifies, by using the image, the position of the sample piece 4 in the xy direction.

The charged particles generated by the irradiation with the electron beam b12 are detected as a detection signal by the charged particle detector 109, and the detection signal is imaged by the detector controller 136. That is, an image (needle image) of the sample piece 4 and the needle 112 viewed from the y-axis positive side is generated. The integrated control unit 130 specifies, by using the image, the position of the sample piece 4 in the zx direction.

The integrated control unit 130 calculates a distance between the sample piece 4 and the pillar 53, that is, the movement amount of the sample piece 4, based on the position of the sample piece 4 specified based on the needle image and the position of the pillar 53 determined based on the LC image. The needle controller 142 moves the needle 112 by the calculated movement amount. Accordingly, the sample piece 4 is moved to a position where the sample piece 4 may be bonded to the pillar 53 of the carrier 5. Thereafter, the above-described deposition and cutting of the needle 112 from the sample piece 4 are performed.

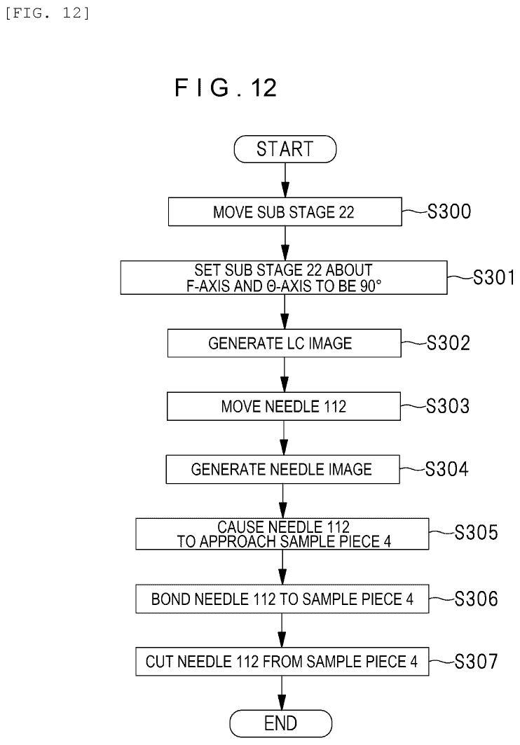

FIG. 12 is a flowchart illustrating an operation flow of the transfer process to be performed by the charged particle beam device 10 in the case where the sample piece 4 is subjected to the cross-sectional automatic sampling. Each process illustrated in FIG. 12 is automatically executed and controlled by the integrated control unit 130. Each process described below is a detail of the process of step S209 executed in the flowchart of FIG. 10 described above.

In step S300, the integrated control unit 130 controls the wafer stage controller 133 to move the x-base 210, the y-base 211, and the z-base 212 in the xy plane and move the sub stage 22 to the lower side (z-axis negative side) of the ion beam column 11 and the electron beam column 12. In step S301, the integrated control unit 130 controls the sub stage controller 134 to move the sub stage 22 to the position where the rotation angles about the F-axis and the θ-axis are both 90°. In step S302, the integrated control unit 130 controls the ion beam column controller 131 to irradiate the carrier 5 with the ion beam b11 from the ion beam column 11. Similarly, the integrated control unit 130 controls the electron beam column controller 132 to irradiate the carrier 5 with the electron beam b12 from the electron beam column 12. The integrated control unit 130 calculates the movement amount from the needle 112 at the retracted position to the pillar 53 by using the LC image generated by the detector controller 136 based on the detection signal detected by the charged particle detectors 109 and 110.

In step S303, the integrated control unit 130 controls the needle controller 142 to move the needle 112 by the movement amount calculated in step S302. In step S304, the integrated control unit 130 controls the ion beam column controller 131 to irradiate the sample piece 4 bonded to the needle 112 with the ion beam b11 from the ion beam column 11. Similarly, the integrated control unit 130 controls the electron beam column controller 132 to irradiate the sample piece 4 bonded to the needle 112 with the electron beam b12 from the electron beam column 12. The integrated control unit 130 calculates the movement amount of the needle 112 to the position where the needle 112 may be bonded to the pillar 53, by using the needle image generated by the detector controller 136 based on the detection signal detected by the charged particle detector 109.

In step S305, the integrated control unit 130 controls the needle controller 142 to move the needle 112 by the movement amount calculated in step S304. In step S306, the integrated control unit 130 causes the needle 112 to bond to a part of the sample piece 4 by the deposition as described above. In step S307, the integrated control unit 130 controls the ion beam column controller 131 to cause the ion beam column 11 to irradiate, with the ion beam b11, the portion 4d where the sample piece 4 and the needle 112 are connected, cuts the needle 112 from the sample piece 4, and ends the transfer process.

### [Transfer Process in Case Where Sample Piece is Subjected to Planar Observation (Planar Automatic Sampling)]

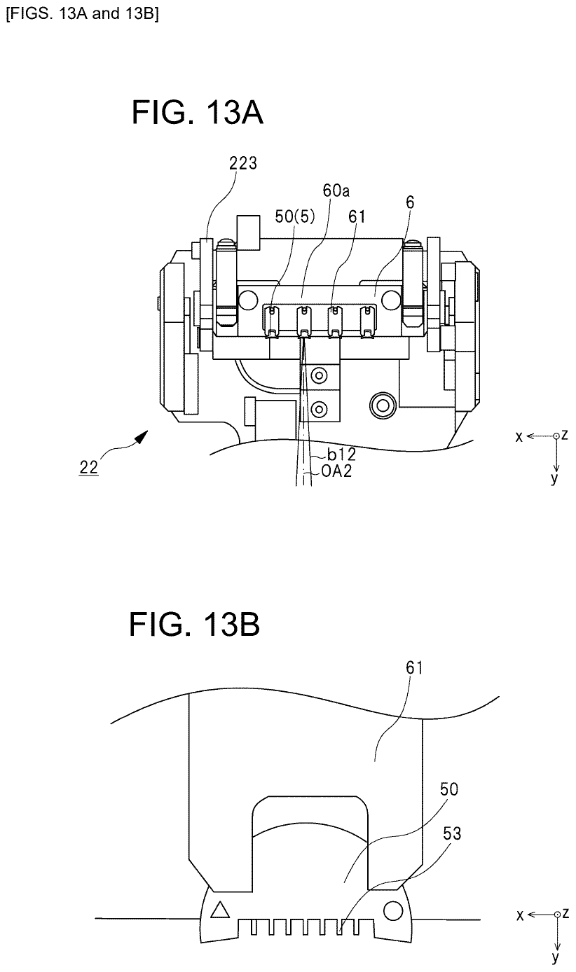

FIG. 13 is a diagram schematically illustrating the appearance of the sub stage 22, the holder 6 attached to the sub stage 22, and the carrier 5 mounted on the holder 6. (A) of FIG. 13 is the appearance of the sub stage 22, the holder 6, and the carrier 5 viewed from the z-axis positive side, and (B) of FIG. 13 is an enlarged appearance of the carrier 5 illustrated in (A) of FIG. 13. In the following description, differences from the case where the sample piece 4 is subjected to the cross-sectional automatic sampling will be mainly described. Points not particularly described are the same as those in the case where the sample piece 4 described above is subjected to the cross-sectional automatic sampling.

As described above, in the case where the sample piece 4 is subjected to the planar automatic sampling, the sub stage 22 is driven to a position where the rotation angle about the F-axis is 0° and the rotation angle about the θ-axis is 90°. Therefore, as illustrated in (A) of FIG. 13 and (B) of FIG. 13, the surface of the base body 50 of the carrier 5 is parallel to the xy plane and faces the z-axis positive side, and the pillar 53 protrudes toward the y-axis positive side. In other words, the surface of the base body 50 of the carrier 5, that is, the observation surface 40 of the sample piece 4 faces the ion beam column 11. In this state, the ion beam column 11 and the electron beam column 12 irradiate the carrier 5 with the ion beam b11 and the electron beam b12, respectively. The following process is performed in the same manner as in the case where the sample piece 4 is subjected to the cross-sectional moving sampling.

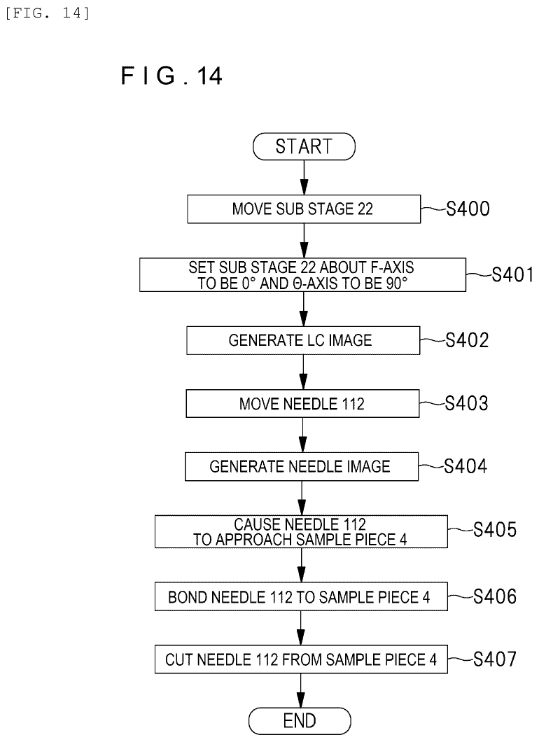

FIG. 14 is a flowchart illustrating an operation flow of the transfer process to be performed by the charged particle beam device 10 in the case where the sample piece 4 is subjected to planar automatic sampling. Each process illustrated in FIG. 14 is automatically executed and controlled by the integrated control unit 130. Each process described below is a detail of the process of step S209 executed in the flowchart of FIG. 10 described above.

The process of step S400 is the same as the process of step S300 in FIG. 12. In step S401, the integrated control unit 130 controls the sub stage controller 134 to drive the sub stage 22 to a position where the rotation angle about the F-axis is 0° and the rotation angle about the θ-axis is 90°. The following processes from step S402 to step S407 are the same as the processes from step S302 to step S307 in FIG. 12.

### [Second Operation]

The charged particle beam device 10 performs a second operation including a preparation process, a processing process, a transfer process, and a finishing process as the production and observation method. In the second operation, the preparation process, the processing process, and the transfer process are also performed in the same manner as in the first operation described above. During the transfer process, posture control automatic microsampling for automatically controlling the posture of the sample piece 4 may be performed. The posture control automatic microsampling will be described in detail later.

In the finishing process, the first method or the second method is performed. In the first method, one sampled sample piece 4 is subjected to finishing, and then another sample piece 4 is sampled from the wafer 3. In the second method, after all the designated number of sample pieces 4 are sampled from the wafer 3, each sample piece 4 is subjected to finishing. Hereinafter, processes of the charged particle beam device 10 that performs the second operation will be described.

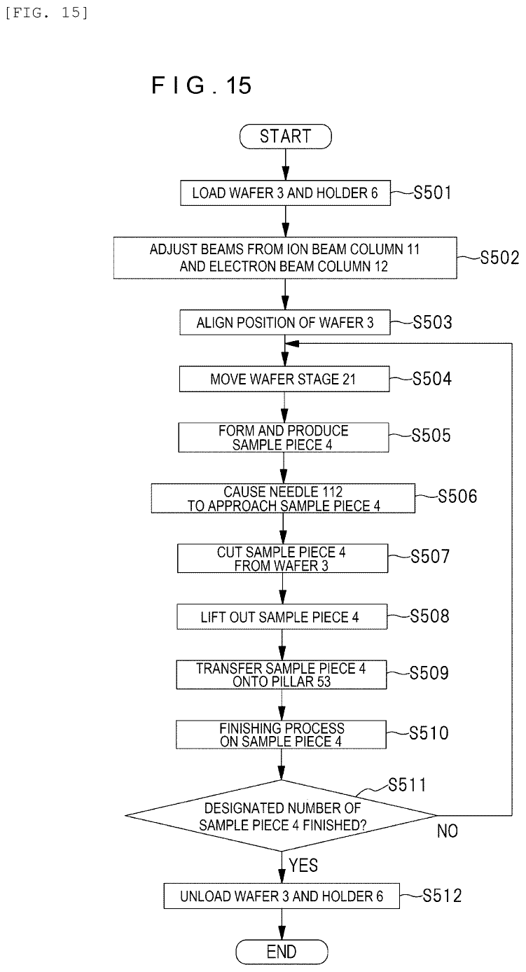

FIG. 15 is a flowchart illustrating the processes of the charged particle beam device 10 in a case where the first method is performed in the finishing process. Each process illustrated in FIG. 15 is automatically executed and controlled by the integrated control unit 130. Processes from step S501 to step S509 are the same as processes from step S201 to step S209 illustrated in FIG. 10 described above.

In step S510, the integrated control unit 130 controls the ion beam column 11, the electron beam column 12, and the sub stage 22 to process the sample piece 4 bonded to the pillar 53 into a thin film piece thickness of, for example, 100 nm or less for TEM observation. Details of the finishing process will be described later.

In step S511, it is determined whether the designated number of sample pieces 4 is formed and produced, transferred onto the carrier 5, and subjected to the finishing process. When each process is performed on the designated number of sample pieces 4, the integrated control unit 130 makes an affirmative determination, and the process proceeds to step S512. When the number of sample pieces 4 subjected to each process described above does not reach the designated number, the integrated control unit 130 makes a negative determination, and the process returns to step S504. In step S512, the integrated control unit 130 performs the same process as in step S212 illustrated in FIG. 10, and ends the processes of the second operation.

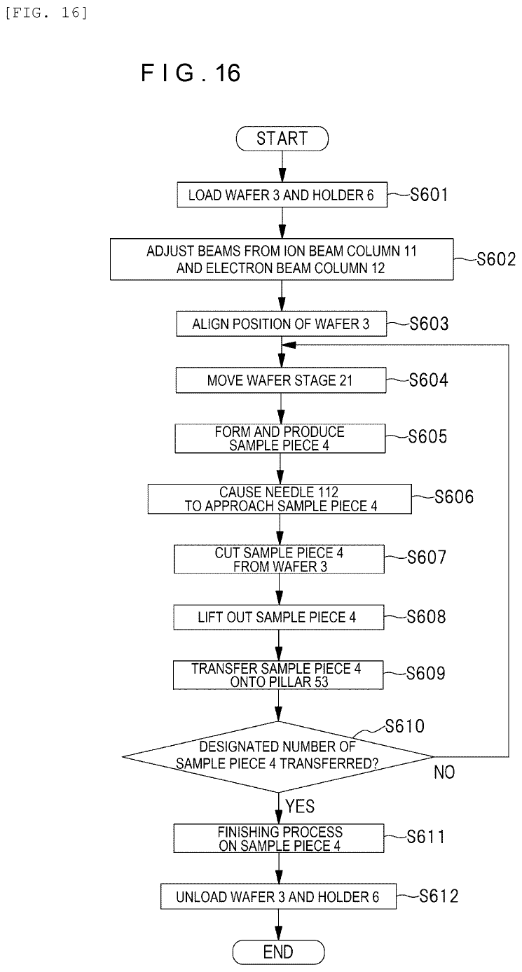

FIG. 16 is a flowchart illustrating processes of the charged particle beam device 10 in a case where the second method is performed in the finishing process. Each process illustrated in FIG. 16 is automatically executed and controlled by the integrated control unit 130. The processes from step S601 to step S609 are the same as the processes from step S201 to step S209 illustrated in FIG. 10.

In step S610, it is determined whether the designated number of sample pieces 4 is formed and produced and transferred onto the carrier 5. When each process is performed on the designated number of sample pieces 4, the integrated control unit 130 makes an affirmative determination, and the process proceeds to step S611. When the number of sample pieces 4 subjected to each process described above does not reach the designated number, the integrated control unit 130 makes a negative determination, and the process returns to step S604.

In step S611, the integrated control unit 130 controls the ion beam column 11, the electron beam column 12, and the sub stage 22 to process each sample piece 4 bonded to the pillar 53 to a thickness of, for example, 100 nm or less for TEM observation. Details of the finishing process will be described later. In step S612, the integrated control unit 130 performs the same process as in step S212 illustrated in FIG. 10, and ends the processes of the second operation.

### [Finishing Process]

Next, details of the finishing process will be described. In both the first method and the second method, each process described below is performed in common during the finishing process. In the finishing process, the sample piece 4 is processed into a thin film piece having a desired thickness (for example, 100 nm or less) by irradiating the observation surface 40 of the sample piece 4 or the back surface of the observation surface 40 with the ion beam b11 by the ion beam column 11. The charged particle beam device 10 includes a first process and a second process as the finishing process, and executes the finishing process in either the first process or the second process. In the first process, the processing is performed in a state where the rotation angle of the sub stage 22 about the F-axis is controlled, so that the incident angle, on the sample piece 4, of the ion beam b11 with which the sample piece 4 is irradiated is changed. In the second process, the processing is performed in a state where the rotation angle of the sub stage 22 about the T-axis is controlled by controlling the rotation angle of the wafer stage 21 about the T-axis, so that occurrence of a curtaining effect on the sample piece 4 is reduced. Hereinafter, each of the first process and the second process will be described in detail.

### [First Process]

In the first process of the finishing process, the sub stage controller 134 drives the sub stage 22 to the position where the rotation angles about the F-axis and the θ-axis are both 90°, as in the case of the transfer process described above when the sample piece 4 described above is subjected to the cross-sectional automatic sampling. That is, as illustrated in (A) of FIG. 11 and (B) of FIG. 11, the surface of the base body 50 of the carrier 5 is parallel to the zx plane and faces the y-axis positive side, and the pillar 53 protrudes toward the z-axis positive side. The sample piece 4 bonded to the pillar 53 towardthe z-axis positive side is irradiated with the ion beam b11 by the ion beam column 11 from the z-axis positive side, so that the sample piece 4 is subjected to finishing.

Since the sub stage 22 is driven (rotated) to the position where the rotation angle about the θ-axis is 90°, the surface (observation surface 40) of the sample piece 4 to which the finishing is subjected may be observed by the electron beam b12. That is, a processing state of the surface of the sample piece 4 to which the finishing is subjected is observed by being imaged based on the electron beam b12 emitted by the electron beam column 12. Prior to the finishing, a processing frame for specifying a region to which the finishing is subjected is set in the sample piece 4. The processing frame is irradiated with the ion beam b11 from the ion beam column 11, so that the sample piece 4 is scraped.

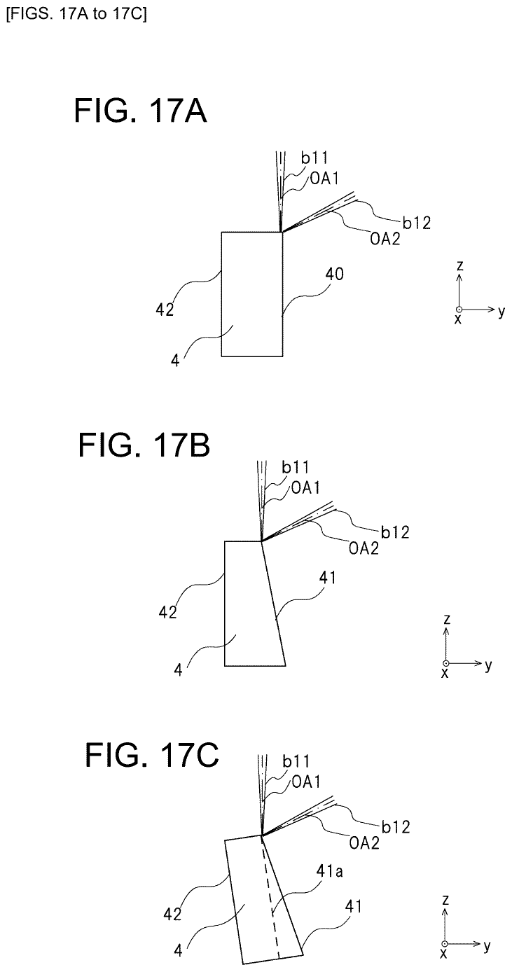

FIG. 17 is a diagram schematically illustrating a relation in a yz plane between the ion beam b11 emitted from the ion beam column 11 and the shape of the sample piece 4. (A) of FIG. 17 illustrates a case where the sub stage 22 is driven to a position where the rotation angle about the F-axis is 90°. At this time, the ion beam b11 is perpendicularly incident, relative to the sample piece 4, on the surface of the sample piece 4 on the z-axis positive side. That is, the sub stage 22 is rotated and tilted around the F-axis such that the optical axis OAl of the ion beam b11 is parallel to the observation surface 40 of the sample piece 4. The observation surface 40 of the sample piece 4 is roughly thinned by irradiation with the ion beam b11 (hereinafter, referred to as first finishing).

(B) of FIG. 17 schematically illustrates the shape of the sample piece 4 after the first finishing. In the first finishing, the processed cross section 41 formed by processing the observation surface 40 of the sample piece 4 is not parallel to the z-axis due to the energy distribution of the emitted ion beam b11, and a tilt occurs. For example, the z-axis negative side of the processed cross section 41 of the sample piece 4 has a shape toward the y-axis positive side rather than the z-axis positive side.

By cutting the protruding portion of the processed cross section 41 of the sample piece 4, the processed cross section 41 of the sample piece 4 is processed to be a vertical cross section (hereinafter, referred to as second finishing). When performing the second finishing, the sub stage controller 134 drives the sub stage 22 such that the rotation angle about the F-axis is changed to (90−α)° without changing the rotation angle about the θ-axis to 90°. αis, for example, an angle in a range of about 1° to 1.5°, and is appropriately set according to beam conditions such as the size of the processed cross section 41 of the sample piece 4 and the beam intensity of the ion beam b11.

(C) of FIG. 17 schematically illustrates a case where the rotation angle about the F-axis is (90−α)°. As illustrated in the drawing, the ion beam b11 is non-perpendicularly incident on the sample piece 4. That is, by changing the tilt of the sub stage 22, the incident angle of the ion beam b11 on the processed cross section 41 of the sample piece 4 is adjusted. Therefore, the protruding portion on the z-axis negative side of the processed cross section 41 of the sample piece 4 is cut by irradiation with the ion beam b11, and the sample piece 4 is processed into a finished cross section 41a indicated by a broken line in (C) of FIG. 17. Accordingly, the finished cross section 41a in which occurrence of tilt is prevented is formed on the sample piece 4.

In the second finishing, the ion beam column controller 131 causes the ion beam column 11 to output the ion beam b11 at lower current than in the first finishing. Therefore, the beam intensity of the ion beam b11 is lower than that in the first finishing, and damage to the sample piece 4 can be reduced.

By irradiating the processed cross section 41 of the sample piece 4 with the electron beam b12 from the electron beam column 12, the processed cross section 41 is imaged, and the processing state of the observation surface 40 is observed. As a result of the observation, the integrated control unit 130 stops the second finishing at a stage when the processed cross section 41 becomes the finished cross section 41a having a desired shape. The observation may be performed by a user checking the generated image, or may be performed by the integrated control unit 130 comparing the image of the processed cross section 41 with a template image obtained by imaging the finished cross section 41a having a desired shape.

Next, finishing is performed on a back surface 42 side of the sample piece 4 (hereinafter referred to as third finishing). When the third finishing is performed, the sub stage controller 134 rotates the sub stage 22 about the θ-axis by 180° from the state of the second finishing, and drives the sub stage 22 to a position where the rotation angle about the θ-axis is −90°. Since the sub stage 22 is driven (rotated) to a position where the rotation angle about the θ-axis is −90°, the surface (back surface 42 of observation surface 40) of the sample piece 4 to which the finishing is subjected may be observed by the electron beam b12. That is, the processing state of the back surface 42 of the sample piece 4 is observed by being imaged based on the electron beam b12 emitted by the electron beam column 12.

The sub stage controller 134 drives the sub stage 22 to a position where the rotation angle about the F-axis is (90+α). The value of α is the same value as in the second finishing. In this state, the ion beam column 11 irradiates the back surface 42 of the sample piece 4 with the ion beam b11. As a result, the back surface 42 of the sample piece 4 is also processed into a vertical cross-sectional shape having no tilt. That is, by changing the tilt of the sub stage 22, the incident angle of the ion beam b11 on the back surface 42 of the sample piece 4 is adjusted, and the finished cross section 41a and the back surface 42 of the sample piece 4 are processed to be in parallel. In the third finishing, the back surface 42 of the sample piece 4 is also irradiated with the electron beam b12 from the electron beam column 12, so that the back surface 42 is imaged and observed. As a result of the observation, the integrated control unit 130 stops the third finishing at a stage when the back surface 42 has a desired shape. In this case, the observation may also be performed by checking the image by the user, or may be performed by comparing the template image with the generated image by the integrated control unit 130.

The sample piece 4 is thinned by the second finishing and the third finishing described above. Cleaning may be performed on the sample piece 4 subjected to the second finishing and the third finishing by a low acceleration ion beam.

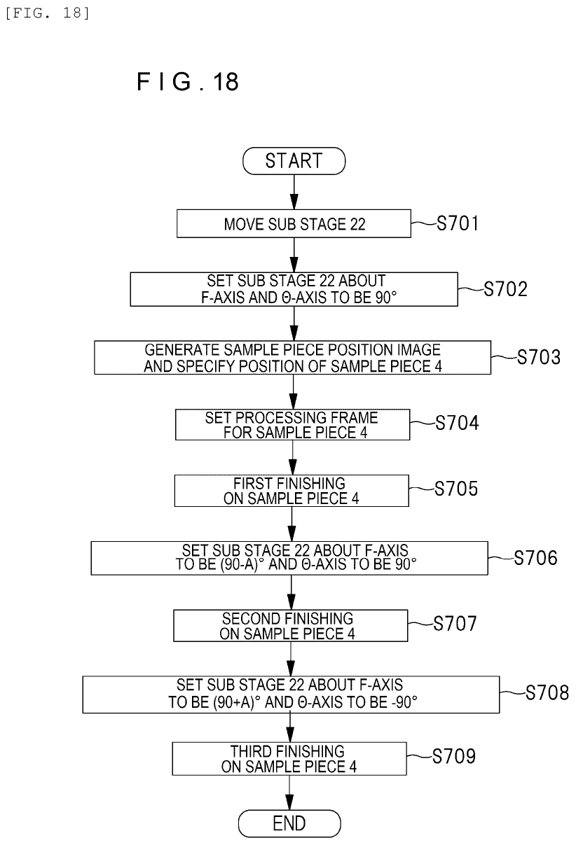

FIG. 18 is a flowchart illustrating an operation flow of the first process of the finishing process to be performed by the charged particle beam device 10. Each process illustrated in FIG. 18 is automatically executed and controlled by the integrated control unit 130. The processes described below are detailed processes of step S510 of FIG. 15 or step S611 of FIG. 16. That is, the processes described below are processes to be performed after the sample piece 4 is transferred onto the pillar 53 of the carrier 5.

In step S701, the integrated control unit 130 controls the wafer stage controller 133 to move the x-base 210, the y-base 211, and the z-base 212 in the xy plane and move the sub stage 22 to the lower side (z-axis negative side) of the ion beam column 11 and the electron beam column 12. When the finishing process is performed by the first method, that is, when the process illustrated in FIG. 15 is performed, the process of step S701 is not performed.

In step S702, the integrated control unit 130 controls the sub stage controller 134 to drive the sub stage 22 to the position where the rotation angles about the F-axis and the θ-axis are both 90°. In step S703, the integrated control unit 130 controls the ion beam column controller 131 to irradiate the sample piece 4 with the ion beam b11 from the ion beam column 11. Similarly, the integrated control unit 130 controls the electron beam column controller 132 to irradiate the sample piece 4 with the electron beam b12 from the electron beam column 12. The integrated control unit 130 recognizes the position of the sample piece 4 by using the image (sample piece position image) generated by the detector controller 136 based on the detection signal detected by the charged particle detector 109, and specifies the position of the sample piece 4 to be subjected to finishing.

In step S704, the integrated control unit 130 sets a processing frame on the observation surface 40 of the sample piece 4 based on the position specified by using the sample piece position image. In step S705, the integrated control unit 130 controls the ion beam column controller 131 to irradiate, with the ion beam b11 from the ion beam column 11, the processing frame set on the observation surface 40 of the sample piece 4. Accordingly, the first finishing is performed.

In step S706, the integrated control unit 130 controls the sub stage controller 134 to drive the sub stage 22 to a position where the rotation angle about the F-axis is (90−α)°. In step S707, the integrated control unit 130 controls the ion beam column controller 131 to irradiate the processed cross section 41 of the sample piece 4 with the ion beam b11 from the ion beam column 11. Accordingly, the second finishing is performed. At this time, the integrated control unit 130 controls the electron beam column controller 132 to irradiate the processed cross section 41 of the sample piece 4 with the electron beam b12 from the electron beam column 12. The integrated control unit 130 images the processed cross section 41 of the sample piece 4 by using the image generated by the detector controller 136 based on the detection signal detected by the charged particle detector 109.

The integrated control unit 130 determines whether the processed cross section 41 of the sample piece 4 is processed into a desired shape, that is, the shape of the finished cross section 41a by comparing the generated image with the template image or the like, for example. When it is determined that the processed cross section 41 of the sample piece 4 is processed into the shape of the finished cross section 41a, the integrated control unit 130 controls the ion beam column controller 131 and the electron beam column controller 132 to stop the irradiation with the ion beam b11 from the ion beam column 11 and the irradiation with the electron beam b12 from the electron beam column 12.

In step 708, the integrated control unit 130 controls the sub stage controller 134 to drive the sub stage 22 to a position where the rotation angle about the θ-axis is −90° and the rotation angle about the F-axis is (90+α). In step S709, the integrated control unit 130 controls the ion beam column controller 131 to irradiate the back surface 42 of the sample piece 4 with the ion beam b11 from the ion beam column 11. Accordingly, the third finishing is performed.

In this case, the integrated control unit 130 also controls the electron beam column controller 132 to irradiate the back surface 42 of the sample piece 4 with the electron beam b12 from the electron beam column 12. The integrated control unit 130 images the back surface 42 of the sample piece 4 by using the image generated by the detector controller 136 based on the detection signal detected by the charged particle detector 109. When it is determined that the back surface 42 of the sample piece 4 is processed into a desired shape based on the generated image in the same manner as in step S707, the integrated control unit 130 ends the third finishing. That is, the integrated control unit 130 controls the ion beam column controller 131 and the electron beam column controller 132 to stop the irradiation with the ion beam b11 from the ion beam column 11 and the irradiation with the electron beam b12 from the electron beam column 12, and ends the finishing process.

### [Second Process]

In the second process of the finishing process, the processing is performed so as to reduce the occurrence of the curtaining effect on the sample piece 4 as described above. The curtaining effect is that unevenness occurs in the degree of scraping of the sample piece 4 irradiated with the ion beam b11 by the ion beam column 11.

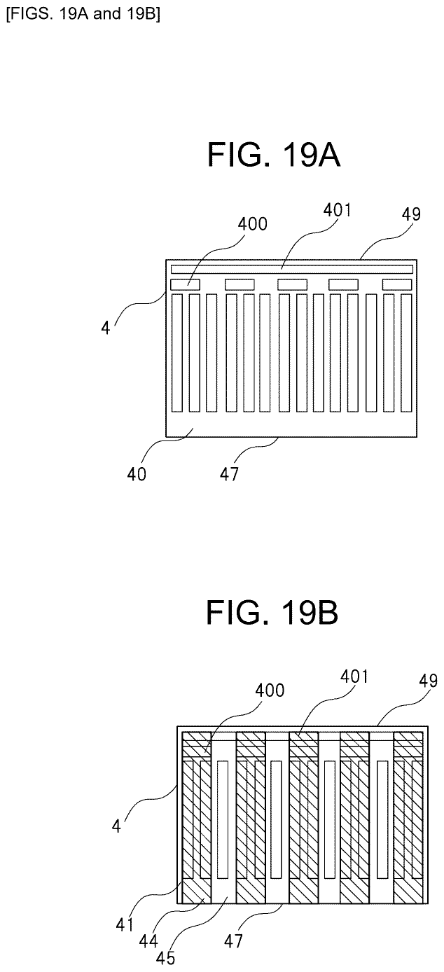

FIG. 19 is a diagram schematically illustrating an appearance of the observation surface 40 of the sample piece 4. (A) of FIG. 19 illustrates a state where the curtaining effect is not generated, and (B) of FIG. 19 illustrates a state where the curtaining effect is generated. The curtaining effect occurs due to the material and shape on the outermost surface 49 side of the sample piece 4 to be processed, that is, on the z-axis positive side of the sample piece 4 transferred onto the carrier 5 mounted on the sub stage 22. For example, when a structure made of a hard material is present on the outermost surface 49 side of the sample piece 4, processing (cutting) by the ion beam b11 emitted from the ion beam column 11 is less likely to progress on a bottom surface 47 side (z-axis negative side) with respect to a structure 400. When a structure 401 made of a material that is easily processed is present on the outermost surface 49 side of the sample piece 4, the processing (cutting) by the ion beam b11 easily progresses. Therefore, streaky processing unevennesses 44 and 45 occur in the processed cross section 41 of the Sample piece 4. The processing unevenness is an unevenness in the thickness of the sample piece 4, and thus becomes an obstacle at the time of performing TEM observation in the subsequent stage.

In the second process, in order to prevent the curtaining effect, the processed cross section 41 of the sample piece 4 is processed in a state where the sample piece 4 is rotated in an in-plane direction of the processed cross section 41. Hereinafter, details will be described. In the second process, the same process as the process performed in the first process described above is also performed up to the process of the first finishing.

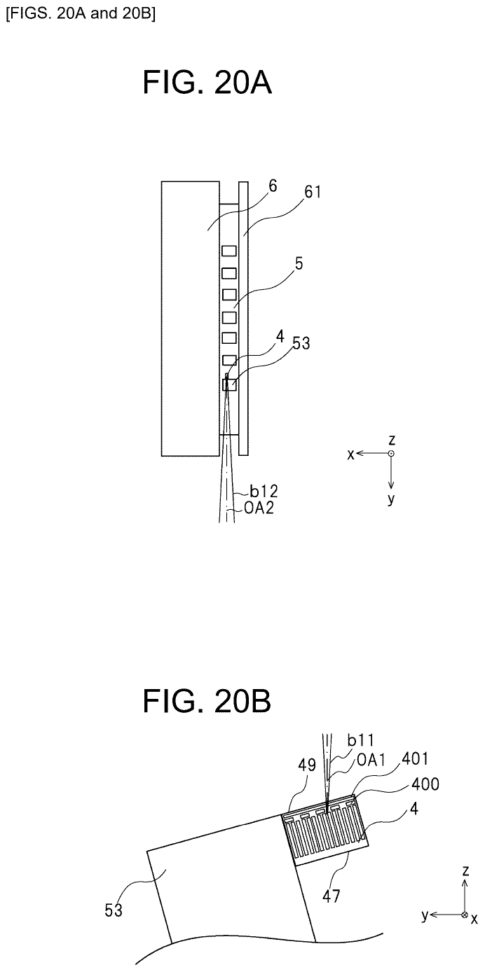

FIG. 20 schematically illustrates the holder 6, the carrier 5, and the sample piece 4 during the second finishing. (A) of FIG. 20 schematically illustrates a case where the holder 6, the carrier 5, and the sample piece 4 are viewed from the z-axis positive side. (B) of FIG. 20 schematically illustrates an enlarged appearance of the sample piece 4 and the pillar 53 of the carrier 5 mounted on the holder 6 when viewed from the x-axis negative side.

In the second finishing, the sub stage controller 134 drives the sub stage 22 to a position where the rotation angle about the θ-axis is 0°. That is, the sub stage 22 rotates such that the processed cross section 41 formed by processing the observation surface 40 of the sample piece 4 and the T-axis, which is a tilt axis of the wafer stage 21 set parallel to the x-axis, intersect each other. Accordingly, a side surface of the pillar 53 of the carrier 5 becomes parallel to the zx plane and faces the electron beam column 12. In addition, the sub stage controller 134 drives the sub stage 22 to a position where the rotation angle about the F-axis is (90+α)° as in the first process.

Further, the wafer stage controller 133 drives the wafer stage 21 to a position where the rotation angle of the wafer stage 21 about the T-axis is 10°. Accordingly, the sub stage 22 provided on the z-base 212 is tilted by 10° relative to the xy plane. The rotation angle about the T-axis is not limited to 10°, and is automatically or manually set to a suitable value according to the shape, size, and the like of the structures 400 and 401 of the sample piece 4.

In this state, the ion beam column 11 irradiates the sample piece 4 with the ion beam b11. Since the rotation angle of the sub stage 22 about the F-axis is (90+α)°, the ion beam b11 is non-perpendicularly incident on the processed cross section 41 of the sample piece 4 as in the first process. Therefore, the protruding portion on the z-axis negative side of the processed cross section 41 of the sample piece 4 is scraped by the irradiation with the ion beam b11, and the finished cross section 41a which is vertical is formed.

Further, the rotation angle about the T-axis is 10°. That is, as illustrated in (B) of FIG. 20, since the wafer stage 21 rotates around the T-axis parallel to the x-axis and is tilted relative to the xy plane, the incident angle of the ion beam b11 from the observation surface 40 of the sample piece 4 on the processed cross section 41 changes. The ion beam b11 whose incident angle changes dodges the structures 400 and 401 on the outermost surface 49 side of the sample piece 4 and irradiates the bottom surface 47 side rather than the structures 400 and 401. As a result, the occurrence of the processing unevennesses 44 and 45 due to the structures 400 and 401 on the outermost surface 49 side of the sample piece 4 is prevented. In the second finishing, the ion beam column controller 131 causes the ion beam column 11 to output the ion beam b11 at a lower current than in the first finishing.

Thereafter, the sub stage controller 134 drives the sub stage 22 to a position where both the rotation angles about the F-axis and the θ-axis are 90°. The wafer stage controller 133 drives the wafer stage 21 to a position where the rotation angle about the T-axis is 0°, and sets the tilt of the sub stage 22 provided on the z-base 212 relative to the xy plane to 0°. That is, the sub stage 22 takes the posture illustrated in (A) of FIG. 11 and (B) of FIG. 11. Accordingly, the processed cross section 41 of the sample piece 4 bonded to the pillar 53 faces the electron beam column 12. In this state, the processed cross section 41 of the sample piece 4 is irradiated with the electron beam b12 from the electron beam column 12, so that the processed cross section 41 is imaged and the processing state is observed. As a result of the observation, the integrated control unit 130 stops the second finishing at a stage when the processed cross section 41 becomes the shape of the finished cross section 41a which is a desired shape.

Next, the third finishing is performed on the back surface 42 side of the sample piece 4. In the third finishing, the sub stage controller 134 drives the sub stage 22 to a position where the rotation angle about the F-axis is (90−α)°, as in the first process. The sub stage controller 134 drives the sub stage 22 to a position where the rotation angle about the θ-axis is 0°, and makes the side surface of the pillar 53 of the carrier 5 parallel to the zx plane to face the electron beam column 12, as in the second finishing. Further, the wafer stage controller 133 drives the wafer stage 21 to a position where the rotation angle about the T-axis is 10°, and tilts the sub stage 22 provided on the z-base 212 by 10° relative to the xy plane.

The ion beam column 11 irradiates the back surface 42 of the sample piece 4 with the ion beam b11. Since the rotation angle of the sub stage 22 about the F-axis is (90−α)° and the rotation angle about the T-axis is 10°, regarding the back surface 42 of the sample piece 4, the back surface 42 is also processed into a vertical cross section in a state where the occurrence of the curtaining effect is prevented. That is, by changing the tilt of the sub stage 22, the incident angle of the ion beam b11 on the back surface 42 of the sample piece 4 is adjusted, and the finished cross section 41a and the back surface 42 of the sample piece 4 are processed to be in parallel.

Thereafter, the sub stage controller 134 drives the sub stage 22 to a position where the rotation angles about the F-axis and the θ-axis are 90° and −90°, respectively. The wafer stage controller 133 drives the wafer stage 21 to a position where the rotation angle about the T-axis is 0°, thereby changing the tilt of the sub stage 22 provided on the z-base 212 relative to the xy plane to 0°.

By the movement of the sub stage 22, the back surface 42 of the sample piece 4 bonded to the pillar 53 faces the electron beam column 12. In this state, the back surface 42 of the sample piece 4 is irradiated with the electron beam b12 from the electron beam column 12, the back surface 42 is imaged, and the processing state is observed. As a result of the observation, the integrated control unit 130 stops the third finishing at a stage when the back surface 42 has a desired shape. By the second process described above, a thin film piece in which the observation surface 40 and the back surface 42 of the sample piece 4 are parallel to each other is formed in a state where the occurrence of the curtaining effect is prevented.

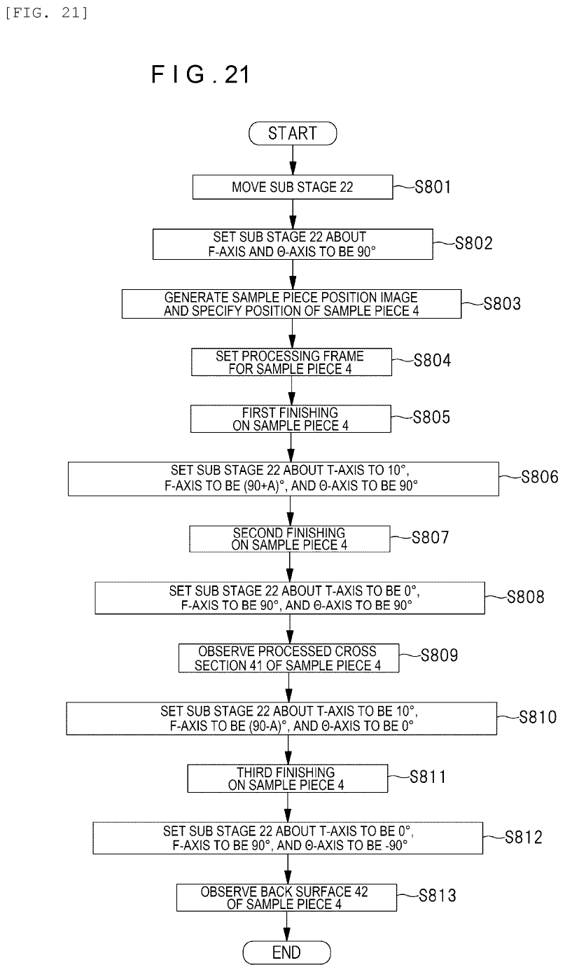

FIG. 21 is a flowchart illustrating an operation flow of the second process of the finishing process to be performed by the charged particle beam device 10. Each process illustrated in FIG. 21 is automatically executed and controlled by the integrated control unit 130. The processes described below are detailed processes of step S510 of FIG. 15 or step S611 of FIG. 16. That is, the processes described below are processes to be performed after the sample piece 4 is transferred onto the pillar 53 of the carrier 5.

The processes from step S801 to step S805 are the same as the processes from step S701 to step S705 in FIG. 18. In step S806, the integrated control unit 130 controls the sub stage controller 134 to drive the sub stage 22 to a position where the rotation angle about the F-axis is (90+α)° and the angle about the θ-axis is 0°. The integrated control unit 130 controls the wafer stage controller 133 to drive the wafer stage 21 to a position where the rotation angle about the T-axis is 10°, and changes the tilt of the sub stage 22 provided on the z-base 212 relative to the xy plane to 10°.

In step S807, the integrated control unit 130 controls the ion beam column controller 131 to irradiate the processed cross section 41 of the sample piece 4 with the ion beam b11 from the ion beam column 11. Accordingly, the second finishing is performed. In step S808, the integrated control unit 130 controls the sub stage controller 134 to drive the sub stage 22 to the position where the rotation angles about the F-axis and the θ-axis are both 90°. The integrated control unit 130 controls the wafer stage controller 133 to drive the wafer stage 21 to a position where the rotation angle about the T-axis is 0°, thereby changing the tilt of the sub stage 22 relative to the xy plane to 0°.

In step S809, the integrated control unit 130 controls the electron beam column controller 132 to irradiate the processed cross section 41 of the sample piece 4 with the electron beam b12 from the electron beam column 12. The integrated control unit 130 images the processed cross section 41 of the sample piece 4 by using the image generated by the detector controller 136 based on the detection signal detected by the charged particle detector 109. The integrated control unit 130 determines whether the processed cross section 41 (that is, the observation surface 40) of the sample piece 4 is processed into the shape of the finished cross section 41a by comparing the generated image with the template image or the like, for example. When it is determined that the sample piece 4 is processed into the shape of the finished cross section 41a, the integrated control unit 130 controls the electron beam column controller 132 to stop the irradiation with the electron beam b12 from the electron beam column 12.

In step S810, the integrated control unit 130 controls the sub stage controller 134 to drive the sub stage 22 to a position where the rotation angle about the F-axis is (90−α)° and the rotation angle about the θ-axis is 0°. The integrated control unit 130 controls the wafer stage controller 133 to drive the wafer stage 21 to a position where the rotation angle about the T-axis is 10°, thereby changing the tilt of the sub stage 22 relative to the xy plane to 10°.

In step S811, the integrated control unit 130 controls the ion beam column controller 131 to irradiate the back surface 42 of the sample piece 4 with the ion beam b11 from the ion beam column 11. Accordingly, the third finishing is performed. In step S812, the integrated control unit 130 controls the sub stage controller 134 to drive the sub stage 22 to a position where the rotation angle of the sub stage 22 about the F-axis is 90° and the rotation angle about the θ-axis is −90°. The integrated control unit 130 controls the wafer stage controller 133 to drive the wafer stage 21 to a position where the rotation angle about the T-axis is 0°, thereby changing the tilt of the sub stage 22 relative to the xy plane to 0°.

In step S813, the integrated control unit 130 controls the electron beam column controller 132 to irradiate the back surface 42 of the sample piece 4 with the electron beam b12 from the electron beam column 12. The integrated control unit 130 images the back surface 42 of the sample piece 4 by using the image generated by the detector controller 136 based on the detection signal detected by the charged particle detector 109. When it is determined that the back surface 42 of the sample piece 4 is processed to the desired shape based on the generated image in the same manner as in step S809, the integrated control unit 130 ends the finishing process. That is, the integrated control unit 130 controls the electron beam column controller 132 to stop the irradiation with the electron beam b12 from the electron beam column 12.

### [Posture Control Automatic Microsampling]

Next, the transfer process when the posture of the sample piece 4 is automatically controlled (posture control automatic microsampling) will be described. The posture control automatic microsampling is a technique of performing microsampling by changing the posture of the sample piece 4 by controlling the rotation direction (that is, angle about R-axis) of the wafer stage 21 at the time of sampling the sample piece 4 from the wafer 3 and the rotation angle of the needle 112 after sampling. The posture of the carrier 5, which is the transfer destination of the sample piece 4 sampled by the posture control automatic microsampling, is changed in accordance with the posture change of the sample piece 4. Accordingly, the posture of the sample piece 4 transferred onto the pillar 53 changes from the posture when being extracted from the wafer 3.

In the following description, a case where the sample piece 4 sampled from the wafer 3 is transferred onto the pillar 53 in a state where an up-down direction of the sample piece 4 is inverted will be described as an example. That is, the sample piece 4 is transferred such that the outermost surface 49 thereof faces the linear portion 51 of the base body 50 of the carrier 5.

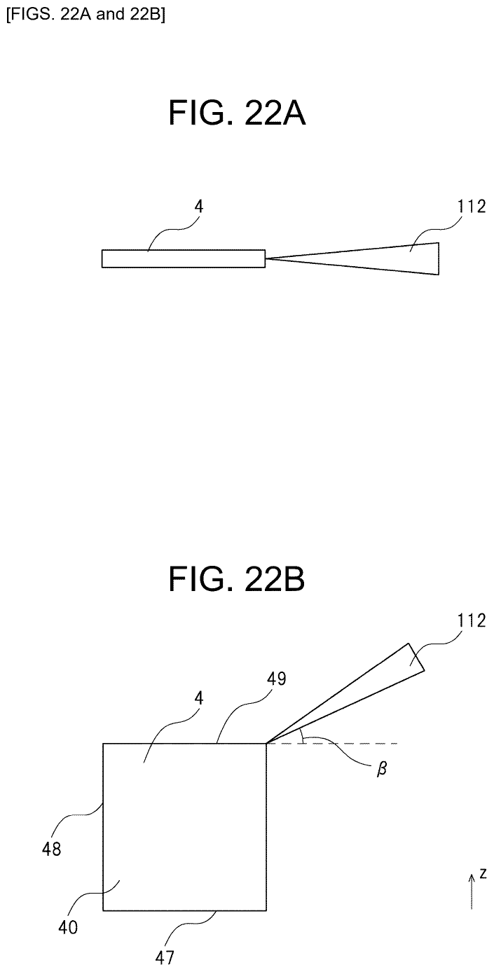

FIG. 22 is a diagram schematically illustrating a positional relation between the sample piece 4 and the needle 112 when the sample piece 4 is sampled from the wafer 3. (A) of FIG. 22 is a view of the sample piece 4 and the needle 112 viewed from the z-axis positive side, and (B) of FIG. 22 is a view of the sample piece 4 and the needle 112 viewed from the observation surface 40 side of the sample piece 4. When the needle 112 is brought close to the sample piece 4, the wafer stage controller 133 rotates the rotation base 213 about the R-axis by about 35°. An angle (approach angle) β formed by the needle 112 relative to the surface of the wafer 3, that is, the xy plane when the sample piece 4 is sampled from the wafer 3 is 30°.

The sub stage controller 134 drives the sub stage 22 to a position where the rotation angle about the F-axis is 0° and the rotation angle about the θ-axis is 54.7°. Accordingly, the surface of the base body 50 of the carrier 5 mounted on the holder 6 attached to the sub stage 22 is parallel to the xy plane and faces the z-axis positive side.

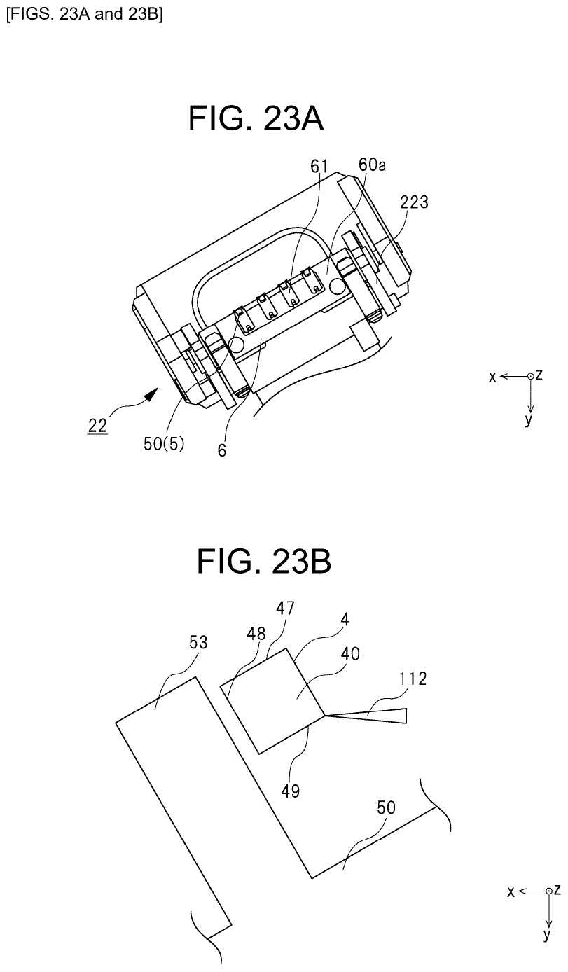

(A) of FIG. 23 is a view of the sub stage 22, the holder 6, and the carrier 5 viewed from the z-axis positive side when the sub stage 22 is moved as described above. (B) of FIG. 23 is a view of the pillar 53 of the carrier 5 and the sample piece 4 approaching the pillar 53 in (A) of FIG. 23 as viewed from the z-axis positive side. Since the rotation angle of the sub stage 22 about the θ-axis is 54.7°, the pillar 53 of the carrier 5 extends at an angle of 54.7° relative to the x-axis. A side surface 48 of the sample piece 4 is bonded to the pillar 53 in a state where the outermost surface 49 of the sample piece 4 faces the base body 50 of the carrier 5.

Specifically, after the sample piece 4 is lifted out from the wafer 3, the needle controller 142 rotates the needle 112 bonded to the sample piece 4 about 110°. As a result, the side surface 48 of the sample piece 4 on a side to which the needle 112 is not bonded faces the pillar 53, and the outermost surface 49 of the sample piece 4 faces the base body 50 of the carrier 5, as illustrated in (B) of FIG. 23.

After the posture of the sample piece 4 with respect to the carrier 5 has the relation illustrated in (B) of FIG. 23, the needle controller 142 moves the needle 112 to a position where the sample piece 4 may be bonded to the pillar 53. Thereafter, the same process as the above-described transfer process is performed to bond the sample piece 4 to the pillar 53 and cut the needle 112 from the sample piece 4.

The sample piece 4 transferred as described above is irradiated with the ion beam b11 from the ion beam column 11 after the rotation angles of the sub stage 22 about the F-axis and the θ-axis are set as in the case of the finishing process described above. That is, the finishing process is performed in a state where the bottom surface 47 of the sample piece 4 transferred onto the pillar 53 is located on the z-axis positive side. In general, when the finishing process is performed by the FIB, the surface of the sample piece 4 irradiated with the ion beam b11, that is, the surface of the sample piece 4 located on the z-axis positive side during the finishing process is most likely to be scraped. Therefore, the surface of the sample piece 4 located on the z-axis positive side may be extremely thin or disappear. In a case where a structure or the like to be observed is present in the vicinity of the outermost surface 49 of the sample piece 4, when the outermost surface 49 of the sample piece 4 is subjected to the finishing process toward the z-axis negative side by the above-described posture control automatic microsampling, the structure to be observed in the vicinity of the outermost surface 49 is prevented from disappearing in the finishing process.

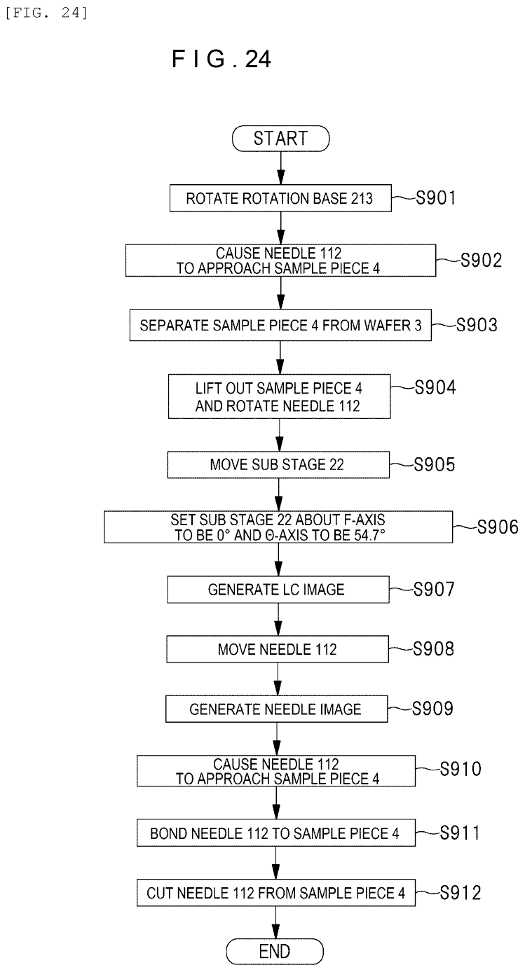

FIG. 24 is a flowchart illustrating an operation flow of a transfer process to be performed by the charged particle beam device 10 when the sample piece 4 is subjected to the posture control automatic microsampling. Each process illustrated in FIG. 24 is automatically executed and controlled by the integrated control unit 130. The processes described below are detailed processes from step S506 to step S509 in FIG. 15 or from step S606 to step S609 in FIG. 17 described above.

In step S901, the integrated control unit 130 controls the wafer stage controller 133 to rotate the rotation base 213 around the R-axis about 35°. In step S902, the integrated control unit 130 controls the needle controller 142 to set the approach angle β of the needle 112 to 30°. Then, the integrated control unit 130 controls the needle controller 142 to move the needle 112 to approach the sample piece 4. The integrated control unit 130 performs deposition to bond the sample piece 4 to a distal end of the needle 112.

In step S903, the integrated control unit 130 controls the ion beam column controller 131 to irradiate, with the ion beam b11, the connection portion 4a (see FIG. 8) where the sample piece 4 and the wafer 3 are connected from the ion beam column 11, and separates the sample piece 4 from the wafer 3. In step S904, the integrated control unit 130 controls the needle controller 142 to lift out the sample piece 4 separated from the wafer 3 and rotate the needle 112 about 110°. In step S905, the integrated control unit 130 controls the wafer stage controller 133 to move the x-base 210, the y-base 211, and the z-base 212 in the xy plane and to move the sub stage 22 to the lower side (z-axis negative side) of the ion beam column 11 and the electron beam column 12.

In step S906, the integrated control unit 130 controls the sub stage controller 134 to drive the sub stage 22 to a position where the rotation angle about the F-axis is 0° and the rotation angle about the θ-axis is 54.7. The processes from step S907 to step S912 are the same as the processes from step S302 to step S307 in FIG. 12.

The approach angle β is not limited to 30°, and can be set to a suitable value according to the shape, size, and the like of the sample piece 4. Further, the rotation angle of the rotation base 213 about the R-axis, the rotation angle of the needle 112, and the rotation angle of the sub stage 22 about the θ-axis have values different from the above-described values according to the value of the approach angle β.

### [Third Operation]

As the third operation, the charged particle beam device 10 performs the above-described preparation process, processing process, and transfer process. That is, in the case of the third operation, the observation process during the first operation and the finishing process during the second operation described above are not performed, and only the sampling of the sample piece 4 is performed.

In this case, the integrated control unit 130 executes the processes of step S201 to step S209, step S211, and step S212 illustrated in the flowchart of FIG. 10.

The holder 6 to which the carrier 5 is attached is transported to the sample piece observation device 30 by the transport mechanism 90, the sample piece 4 being transferred onto the carrier 5 by the first operation, the second operation, or the third operation described above. Then, the TEM device included in the sample piece observation device 30 performs cross-sectional observation or planar observation with a TEM image.

According to the embodiment described above, at least one of the following effects can be exerted.

(1) The charged particle beam device 10 includes the wafer stage 21 configured to move with the wafer 3 placed thereon, the needle 112 configured to hold the sample piece 4 separated and extracted from the wafer 3 and to transport the sample piece 4 to the plurality of carriers 5 mounted on the holder 6, and the sub stage 22 on which the holder 6 is detachably mounted and which moves independently of the wafer stage 21. Accordingly, since the posture of the plurality of carriers 5 mounted on the holder 6 can be controlled to be different from the posture of the wafer 3 independently of the wafer stage 21, the transfer efficiency of the sample piece 4 can be improved while increasing the number of sample pieces 4 that may be transferred onto the carriers 5.

In addition, since the holder 6 is detachably mounted on the sub stage 22, only the holder 6 removed from the sub stage 22 is transported, so that a large transport mechanism is not required, and the sample piece 4 is easily transported, as compared with the related art in which the wafer stage and the holder are integrally transported. In addition, in a case where the wafer stage and the holder are integrally transported as in the related art, when the wafer stage is miniaturized in order to reduce the difficulty of transport, the size of the wafer that may be placed on the wafer stage is limited. On the other hand, since only the holder 6 is transported in the present embodiment, it is unnecessary to reduce the size of the wafer stage 21, and it is possible to prevent the size of the wafer 3 placed on the wafer stage 21 from being limited.

(2) The sub stage 22 is provided on the z-base 212 and is tilted around a θ-axis extending in a direction intersecting the z-base 212 and an F-axis extending in a direction intersecting the θ-axis. Accordingly, the posture of the sub stage 22 may be controlled by two axes independently of the wafer stage 21.

(3) The sub stage 22 includes the tilt mechanism 223 configured to tilt the holder 6. The holder 6 has the plurality of carriers 5 mounted thereon and is attachable to and detachable from the sub stage 22 independently of the tilt mechanism 223. Accordingly, it is possible to control the posture of the holder 6 detachably mounted on the sub stage 22. In addition, only the holder 6 may be transported by the transport mechanism 90.

(4) The charged particle beam device 10 performs a first operation including a processing process, a transfer process, and an observation process as a method for producing and observing the sample piece 4. In the processing process, the wafer 3 is irradiated with the ion beam b11, and the sample piece 4 having a plane or a cross section of the wafer 3 as the observation surface 40 is processed. In the transfer process, the needle 112 is attached to the processed sample piece 4 to extract and separate the sample piece 4 from the wafer 3. The sample piece 4 is attached to the carrier 5 on the holder 6 mounted on the sub stage 22 that is tiltable and rotatable such that the observation surface 40 is parallel to the surface of the carrier 5. In the observation process, the sub stage 22 is rotated such that the observation surface 40 of the sample piece 4 and the back surface 42 of the observation surface 40 may be observed with the electron beam b12. Accordingly, since the posture of the sub stage 22 is controlled independently of the wafer stage 21, posture control at the time of transferring the lifted-out sample piece 4 onto the carrier 5 and posture control at the time of observing the sample piece 4 transferred onto the carrier 5 are facilitated, and the efficiency of the transfer process and the observation process can be improved.

(5) The charged particle beam device 10 performs a second operation including a processing process, a transfer process, and a first method of a finishing process as a method for producing and observing the sample piece 4. In the first method of the finishing process, the observation surface 40 or the back surface 42 of the sample piece 4 is processed by irradiation with the ion beam b11 to thin the sample piece 4. By rotating the sub stage 22 about the F-axis such that the observation surface 40 and the back surface 42 are processed to be in parallel, the tilt of the sub stage 22 is changed, and the incident angle of the ion beam b11 on the observation surface 40 or the back surface 42 is adjusted. The observation surface 40 or the back surface 42 processed by the ion beam b11 is irradiated with the electron beam b12, and the processing state of the observation surface 40 or the back surface 42 is observed. Accordingly, since the posture of the sub stage 22 is controlled independently of the wafer stage 21, the posture control of the sample piece 4 during the finishing process can be facilitated, and the efficiency of the finishing process can be improved.

(6) The charged particle beam device 10 performs a second operation including a processing process, a transfer process, and a second method of a finishing process as a method for producing and observing the sample piece 4. In the second method of the finishing process, the sub stage 22 is tilted around the F-axis such that the observation surface 40 of the sample piece 4 is parallel to the optical axis OA1 of the ion beam b11. The sub stage 22 is rotated about the θ-axis such that the T-axis, which is the tilt axis of the wafer stage 21, intersects the observation surface 40. The wafer stage 21 is tilted around the T-axis such that the incident angle of the ion beam b11 on the observation surface 40 of the sample piece 4 changes. The observation surface 40 or the back surface 42 of the sample piece 4 is processed by the irradiation with the ion beam b11 to thin the sample piece 4. By rotating the sub stage 22 about the F-axis such that the observation surface 40 and the back surface 42 are processed to be in parallel, the tilt of the sub stage 22 is changed, and the incident angle of the ion beam b11 on the observation surface 40 or the back surface 42 is adjusted. The sub stage 22 is rotated about the θ-axis such that the observation surface 40 or the back surface 42 processed by the ion beam b11 may be observed by irradiation with the electron beam b12, and the processing state of the observation surface 40 or the back surface 42 is observed. Accordingly, when the sub stage 22 is tilted about the T-axis, the incident angle of the ion beam b11 on the observation surface 40 of the sample piece 4 changes in the plane of the observation surface 40, and thus it is possible to perform the finishing process that prevents the occurrence of the curtaining effect.

Embodiments of the present disclosure have been specifically described above, but are not limited to the above-described embodiments, and various modifications can be made without departing from the scope of the invention. In each embodiment, components can be added, deleted, replaced, or the like except for essential components. Unless otherwise specified, each component may be single or plural. The embodiments can be combined.

### REFERENCE SIGNS LIST

1: test system
3: wafer
4: sample piece
5: carrier
6: holder
10: charged particle beam device
11: ion beam column
12: electron beam column
21: wafer stage
22: sub stage
40: observation surface
41: processed cross section
42: back surface
112: needle
130: integrated control unit
210: x-base
211: y-base
212: z-base
213: rotation base
214: support mechanism
221: mounting portion
222: mounting support portion
223: tilt mechanism

1.-6. (canceled)

7. A charged particle beam device that creates a sample piece from a wafer by using a charged particle beam, the device comprising:
a charged particle beam column configured to emit the charged particle beam;
a wafer stage configured to move with the wafer placed thereon;
a sample piece transfer mechanism configured to hold the sample piece separated and extracted from the wafer and transport the sample piece to a plurality of carriers mounted on a sample piece holder; and
a sample piece holder stage provided on the wafer stage configured to allow the sample piece holder to be detachably mounted thereon and to move independently of the wafer stage.

8. The charged particle beam device according to claim 7, wherein
the wafer stage includes
an X-base configured to move in a first direction,
a Y-base provided on the X-base, movable in the first direction together with the X-base, and movable in a second direction intersecting the first direction,
a Z-base provided on the Y-base, movable in the first direction together with the X-base and the Y-base, movable in the second direction together with the Y-base, and movable in a third direction intersecting the first direction and the second direction,
a rotation base provided on the Z-base, and configured to allow the wafer to be placed thereon, and rotate about a first axis extending in a direction intersecting the Z-base, and
a support mechanism configured to rotatably support the X-base, the Y-base, the Z-base, and the rotation base about a second axis extending in a direction intersecting the first axis, and
the sample piece holder stage is provided on the Z-base and is tilted around a third axis extending in the direction intersecting the Z-base and a fourth axis extending in a direction intersecting the third axis.

9. The charged particle beam device according to claim 7, wherein
the sample piece holder stage has a tilt mechanism configured to tilt the sample piece holder, and
the sample piece holder is mounted with a plurality of the carriers and is attachable to and detachable from the sample piece holder stage independently of the tilt mechanism.

10. A method for producing and observing a sample piece, the method comprising:
irradiating a wafer placed on a wafer stage with an ion beam to process the sample piece having a plane or a cross section of the wafer as an observation surface;
attaching a sample piece transfer mechanism to the processed sample piece to extract and separate the sample piece from the wafer;
attaching the sample piece to a carrier on a sample piece holder detachably mounted on a sample piece holder stage that is provided on the wafer stage and is tiltable and rotatable with respect to the wafer stage, such that the observation surface is parallel to a surface of the carrier;
rotating the sample piece holder stage such that the observation surface of the sample piece is observable with an electron beam; and
rotating the sample piece holder stage such that a back surface of the observation surface of the sample piece is observable with the electron beam.

11. A method for producing and observing a sample piece, the method comprising:
irradiating a wafer placed on a wafer stage with an ion beam to process the sample piece having a plane or a cross section of the wafer as an observation surface;
attaching a sample piece transfer mechanism to the processed sample piece to extract and separate the sample piece from the wafer;
attaching the sample piece to a carrier on a sample piece holder detachably mounted on a sample piece holder stage that is provided on the wafer stage and is tiltable and rotatable with respect to the wafer stage, such that the observation surface is parallel to a surface of the carrier;
tilting the sample piece holder stage such that the observation surface is parallel to an optical axis of the ion beam;
rotating the sample piece holder stage such that the observation surface or a back surface of the observation surface is observable with an electron beam;
processing the observation surface or the back surface of the sample piece by irradiation with the ion beam to thin the sample piece;
changing a tilt of the sample piece holder stage to adjust an incident angle of the ion beam on the observation surface or the back surface such that the observation surface and the back surface are processed in parallel; and
irradiating, with the electron beam, the observation surface or the back surface processed by the ion beam to observe a processing state of the observation surface or the back surface.

12. A method for producing and observing a sample piece, the method comprising:
irradiating a wafer placed on a wafer stage with an ion beam to process the sample piece having a plane or a cross section of the wafer as an observation surface;
attaching a sample piece transfer mechanism to the processed sample piece to extract and separate the sample piece from the wafer;
attaching the sample piece to a carrier on a sample piece holder detachably mounted on a sample piece holder stage that is provided on the wafer stage and is tiltable and rotatable with respect to the wafer stage, such that the observation surface is parallel to a surface of the carrier;
tilting the sample piece holder stage such that the observation surface is parallel to an optical axis of the ion beam;
rotating the sample piece holder stage such that the observation surface intersects a tilt axis of a stage on which the sample piece holder stage is mounted;
tilting the stage around the tilt axis such that an incident angle of the ion beam on the observation surface varies;
processing the observation surface of the sample piece or a back surface of the observation surface by irradiation with the ion beam to thin the sample piece;
changing a tilt of the sample piece holder stage to adjust an incident angle of the ion beam on the observation surface or the back surface such that the observation surface and the back surface are processed in parallel; and
rotating the sample piece holder stage such that the observation surface or the back surface processed by the ion beam is observable by irradiation with an electron beam, and observing a processing state of the observation surface or the back surface.

13. The charged particle beam device according to claim 7, further comprising:
a transport mechanism configured to transport the sample piece holder on which the plurality of carriers are mounted.
